(19) United States
(12) Patent Application Publication
(10) Pub. No.: US 2011/0192951 A1
(43) Pub. Date: Aug. 11, 2011

(54) PORTABLE PLATFORM FOR IMAGING DEVICE

(76) Inventor: Gerard R Gooch, Buffalo, NY (US)

(21) Appl. No.: 13/024,424

(22) Filed: Feb. 10, 2011

Related U.S. Application Data
(60) Provisional application No. 61/302,969, filed on Feb. 10, 2010.
(60) Provisional application No. 61/303,665, filed on Feb. 11, 2010.

(51) Int. Cl. H05K 7/14; F16B 2/20

(52) U.S. Cl. 248/316.7; 248/309.1

(57) ABSTRACT

A platform for an imaging device is provided. The platform comprises a (a) clip, (b) a rigid, deformable arm which extends from the clip and which has a resilient foam covering disposed over the surface thereof, and (c) a mount which is disposed on said arm. The mount releasably attaches the platform to an imaging device.

### CROSS-REFERENCE TO RELATED APPLICATIONS

The present application claims priority to U.S. Provisional Application Ser. No. 61/302,969, entitled “Portable Universal Camera Device Support Apparatus”, filed on Feb. 10, 2010, which is incorporated herein by reference in its entirety; and to U.S. Provisional Application Ser. No. 61/303,665, entitled “Portable Universal Camera Device Support Apparatus”, filed on Feb. 11, 2010, which is incorporated herein by reference in its entirety.

### FIELD OF THE DISCLOSURE

The present disclosure relates generally to accessories for cameras, video recorders and other imaging devices, and more particularly to platforms for supporting imaging devices.

### BACKGROUND OF THE DISCLOSURE

A variety of support platforms for cameras, video recorders and other imaging devices have been developed in the art. Such platforms minimize the movement and vibration the device experiences during imaging, thus allowing for higher quality images and recordings, and also allow the device to operate in a hands-free manner and to be maintained at the proper orientation during imaging.

Support platforms currently known to the art include conventional tripods of the type depicted in FIGS. 1-2. As seen in FIG. 1, these devices have three supporting legs which are separately adjustable, and are equipped with a threaded protrusion on the mounting platform thereof which may be rotatingly engaged with a complimentary shaped aperture provided in the body of the imaging device to ensure that the imaging device remains firmly seated on the mounting platform during operation.

While tripods of the type depicted in FIGS. 1-2 function well for their intended purpose, they are relatively bulky, and hence inconvenient for everyday usage by the average consumer. Consequently, a number of smaller, more mobile platforms have been developed in the art which are geared towards the average consumer. The smaller, lightweight tripod depicted in FIGS. 3-4 is an example of such a device.

Over time, the initial concept of a tripod has continued to evolve, and this evolution has extended to the smaller, consumer-oriented versions of tripods as well. In particular, designers of these devices have recognized that it is frequently necessary to use these devices on uneven surfaces. The conventional tripods depicted in FIGS. 1-2 overcome this issue by providing elements in each of the legs of the devices that allow the legs to be individually telescopically adjusted to the proper length. However, this approach requires multiple adjustment steps, as each leg must be separately adjusted and, in some cases, readjusted, until the desired height and orientation of the tripod is finally achieved. It is thus desirable to provide a simpler means of achieving the same effect. Since consumer devices have become increasingly smaller and light-weight, the weight-bearing capacity of the tripod is less of a concern.

The foregoing considerations have led to the development of a new generation of miniature tripods with somewhat flexible, multi jointed legs. The devices of FIGS. 5-7 are exemplary of this class of devices. As with their larger predecessors, these devices are provided with a threaded protrusion which rotatingly engages a complimentary shaped aperture in the body of the imaging device as seen in FIG. 5. However, the multi-jointed legs of these devices allow the legs to be readily deformed (within certain limits) as necessary to allow the device to quickly and readily achieve a desired orientation, as illustrated in FIG. 7, and yet provide sufficient rigidity to support the weight of the device and to maintain it in a fixed orientation. Moreover, unlike conventional tripods, the deformability of these devices also allows these platforms to be mounted at least loosely on certain non-planar surfaces, such as railings of sufficient diameter.

Other platforms have also been developed for imaging devices that are not tripodal. For example, FIG. 8 illustrates a combination camera grip and monopod. The handgrip on this device extends vertically from the platform when the device is being used as an accessory to steady a hand-held imaging device, but folds up to serve as a monopod when the device is to be used to support an imaging device on a surface.

FIGS. 9-11 depict another example of a monopod. The single leg on this device has a flexible, multiple joint construction, similar to the legs of the tripods depicted in FIGS. 5-7. This construction allows the device to be wrapped around various objects so that the platform may support an electronic device such as a personal media player. In some embodiments, the device may be equipped with a clip, as shown in FIG. 10. In other embodiments, as shown in FIG. 11, the device may be equipped on one end with a threaded protrusion adapted to rotatingly engage a complimentary shaped aperture in a camera or other such device.

Other monopods are also known to the art. For example, the monopod in FIG. 12 is equipped on one end with a suction cup which allows it to be mounted on a dashboard or other smooth surface. The monopod is provided on the other end with a threaded protrusion adapted to rotatingly engage a complimentary shaped aperture in a camera or other such device.

The monopod in FIG. 13 is a further example of this type of device. This monopod is designed to resemble a snake and is self-supporting by virtue of its coils. It is equipped on one end with a threaded protrusion adapted to rotatingly engage a complimentary shaped aperture in a camera, thus allowing the camera to be supported on a substrate.

### BRIEF DESCRIPTION OF THE DRAWINGS

FIG. 1 is an illustration of a first embodiment of a prior art tripod.

FIG. 2 is an illustration of a second embodiment of a prior art tripod.

FIGS. 3-4 are illustrations of a third embodiment of a prior art tripod.

FIG. 5 is an illustration of a fourth embodiment of a prior art tripod.

FIG. 6 is an illustration of a fifth embodiment of a prior art tripod.

FIG. 7 is an illustration of a sixth embodiment of a prior art tripod.

FIG. 8 is an illustration of a first embodiment of a prior art monopod.

FIGS. 9-10 are illustrations of a second embodiment of a prior art monopod.

FIG. 11 is an illustration of a platform which may be used in conjunction with the monopod of FIGS. 9-10 to mount an imaging device on the monopod.

FIG. 12 is an illustration of a third embodiment of a prior art monopod.

FIG. 13 is an illustration of a fourth embodiment of a prior art monopod.

FIGS. 14-16 are illustrations of a first embodiment of a monopod in accordance with the teachings herein.

FIG. 17 is an exploded view of the monopod of FIG. 15.

FIG. 18 is a cross-sectional view taken along LINE 18-18 of FIG. 15.

FIGS. 19-20 are perspective views showing the dimensions of a particular, non-limiting embodiment of the clamp from the monopod of FIG. 23.

FIG. 21 is a close-up view of the hand wheel of the monopod of FIG. 14.

FIG. 22 is an illustration of the monopod of FIG. 14 mounted on a tree trunk.

FIG. 23 is an illustration of the monopod of FIG. 14 mounted on a fence.

FIG. 24 is an illustration of the monopod of FIG. 14 mounted on the limb of a tree.

FIG. 25 is an illustration of the monopod of FIG. 14 mounted the edge of a table.

FIG. 26 is a disassembled view of the monopod of FIG. 14 depicting the components thereof.

FIGS. 27-28 depict the main structural element of the arm of the monopod of FIG. 14.

FIGS. 29-45 illustrate a particular, non-limiting method for manufacturing a monopod with a braided wire core in accordance with the teachings herein.

### SUMMARY OF THE DISCLOSURE

In one aspect, a platform for an imaging device is provided. The platform comprises a (a) clip, (b) a rigid, deformable arm which extends from the clip and which has a resilient foam covering disposed over the surface thereof, and (c) a mount which is disposed on said arm. The mount releasably attaches the platform to an imaging device.

In another aspect, a method for making a platform for an imaging device is provided which comprises (a) providing a rigid, deformable arm which comprises a particulate mass disposed within a flexible enclosure; (b) attaching a first end of the arm to a first mount which releasably attaches to a substrate; and (c) attaching a second end of the arm to a second mount which releasably attaches to an imaging device.

In a further aspect, a method is provided for making a platform for an imaging device. The method comprises (a) providing a first construct comprising a braided wire disposed within a hollow flexible tubing; and (b) attaching first and second mounts to first and second opposing ends of the first construct, thereby creating a second construct; wherein the first mount releasably attaches to a substrate, and wherein the second mount releasably attaches to an imaging device.

In still another aspect, a platform for an imaging device is provided. The platform comprises a braided wire disposed within a hollow flexible tubing, and first and second mounts attached to first and second opposing ends of said first construct. The first mount releasably attaches to a substrate, and the second mount releasably attaches to an imaging device.

In another aspect, a platform for an imaging device is provided. The platform comprises (i) a rigid, deformable arm containing a core material disposed within a flexible enclosure, wherein said core material is selected from the group consisting of (a) a particulate mass, and (b) a braided wire; and (ii) first and second connectors attached to first and second opposing ends of said arm, wherein said second connector releasably attaches to an imaging device.

### DETAILED DESCRIPTION

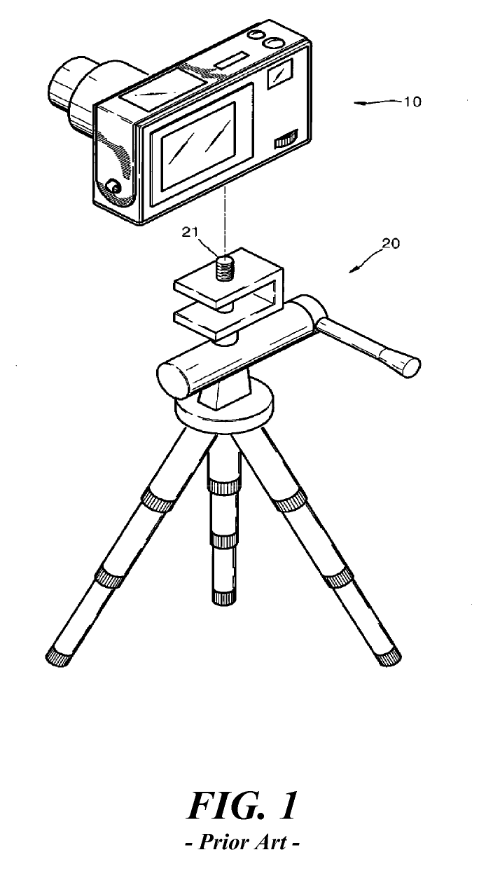

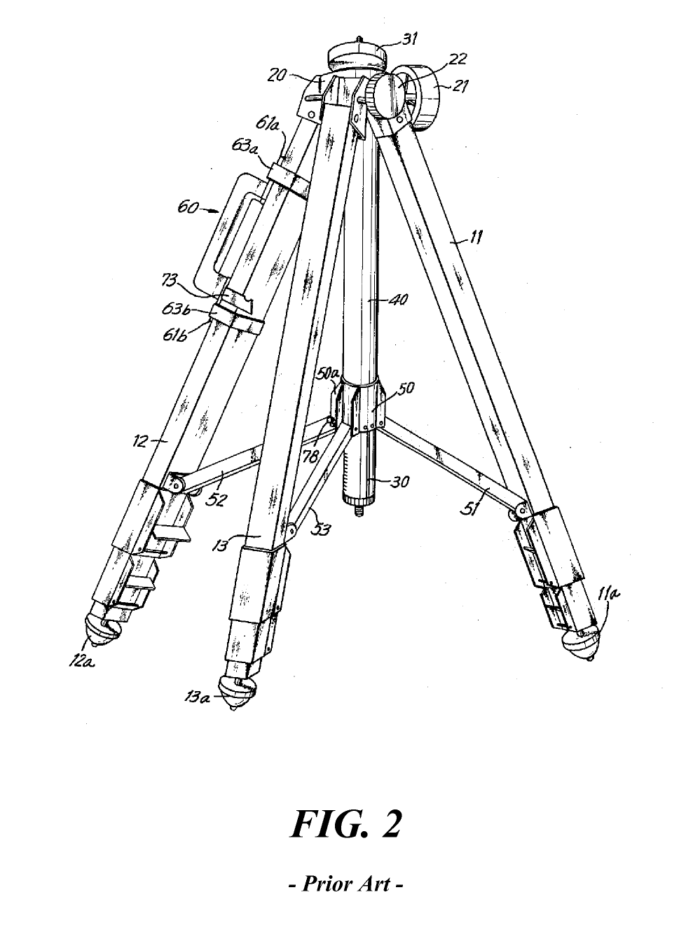

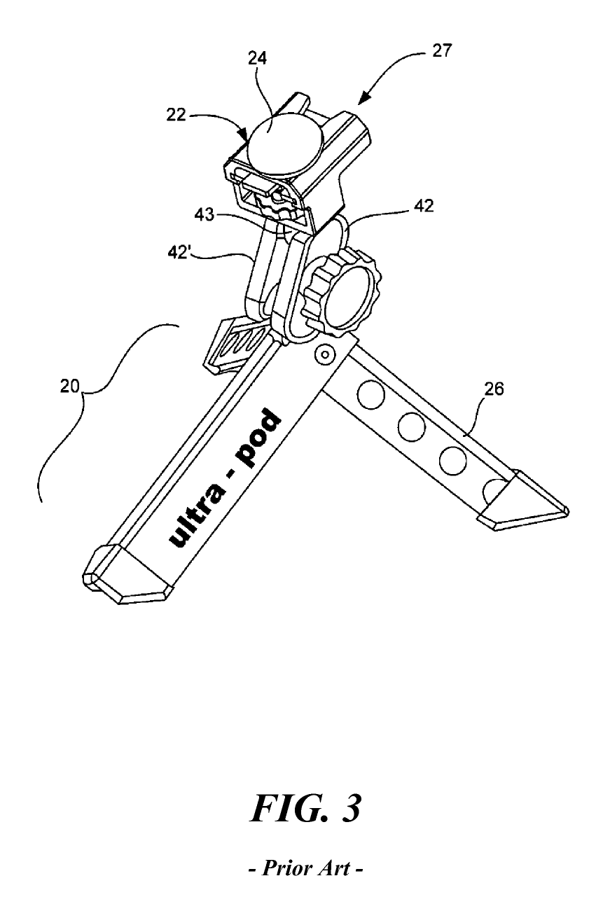

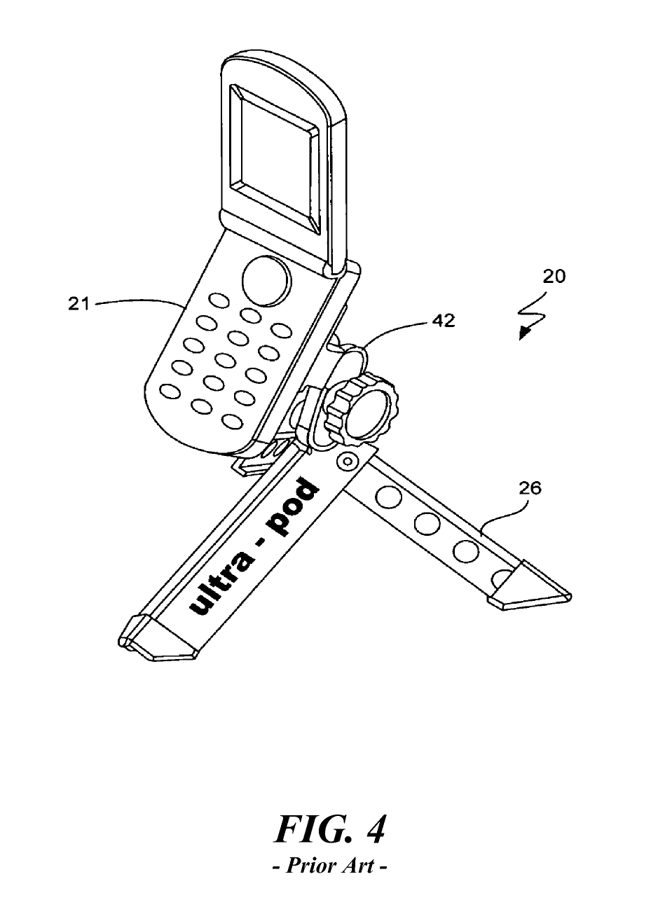

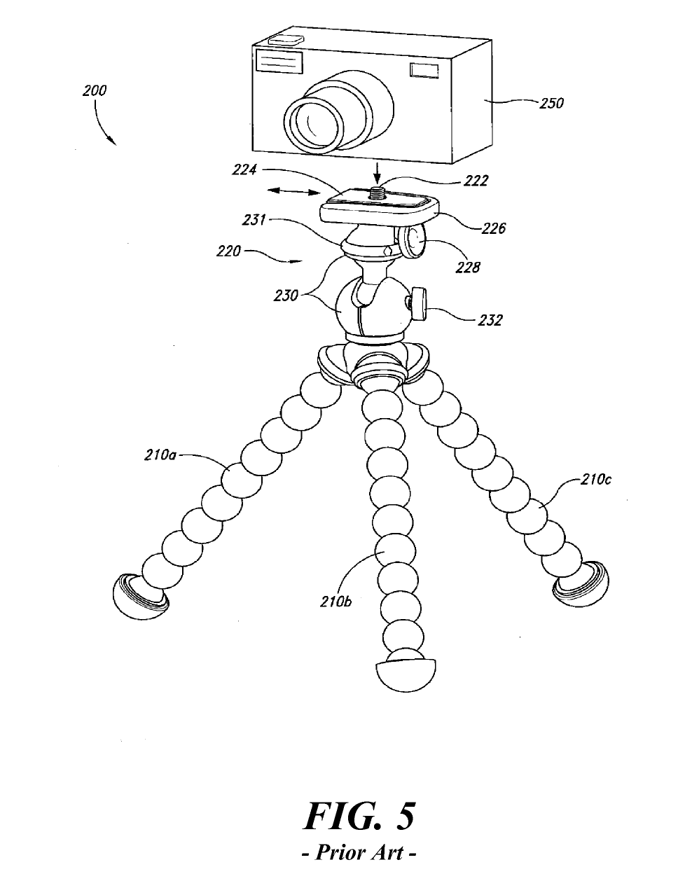

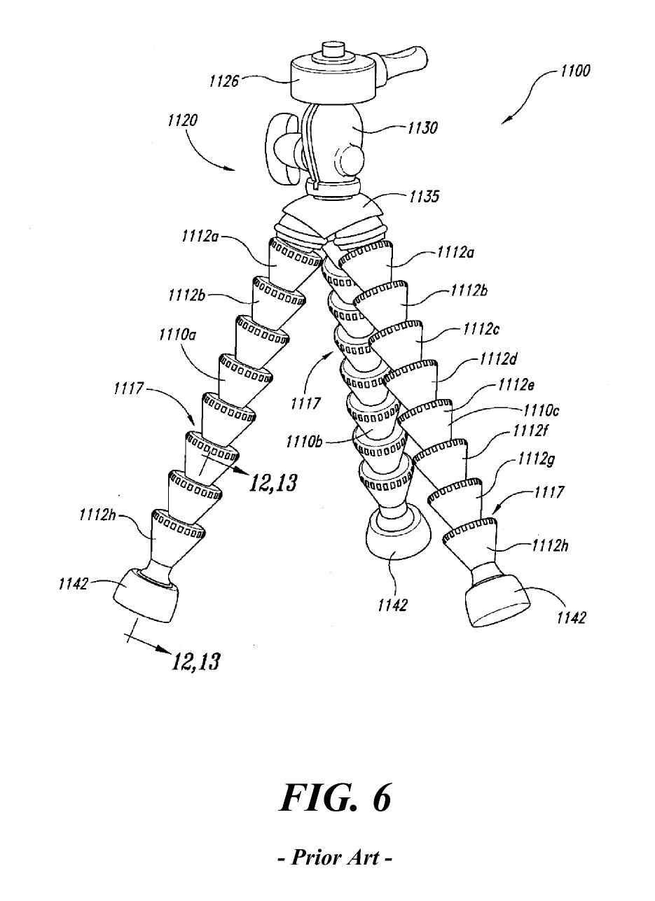

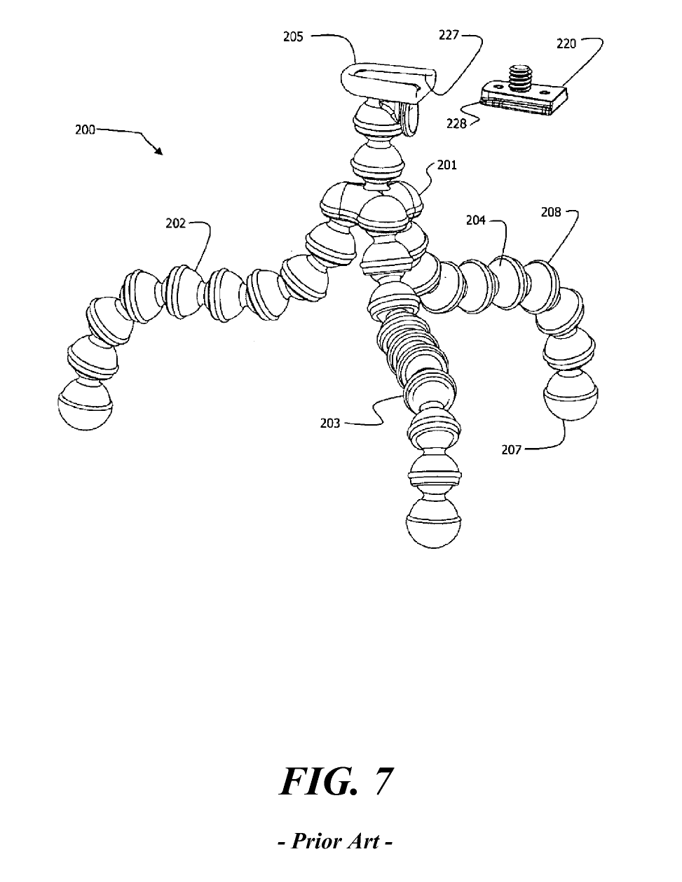

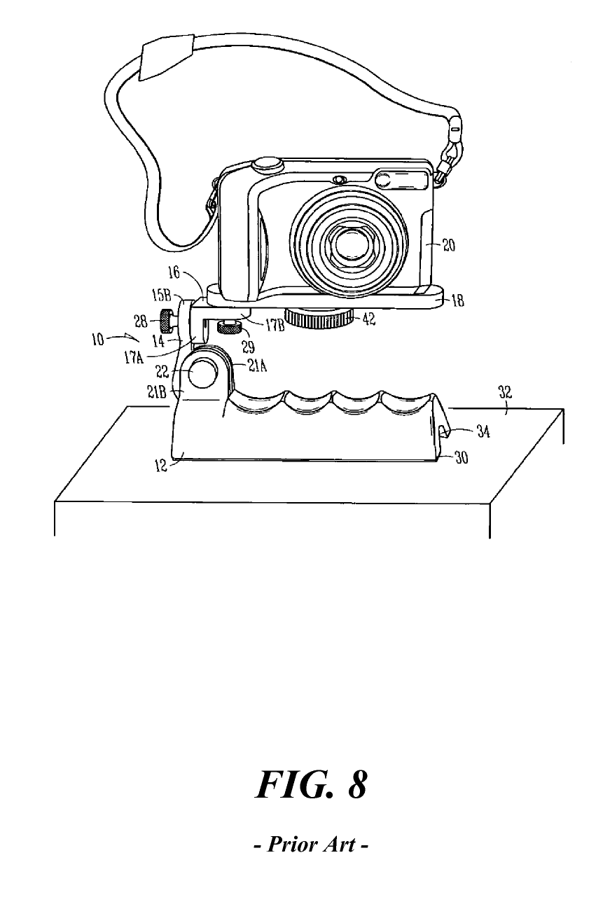

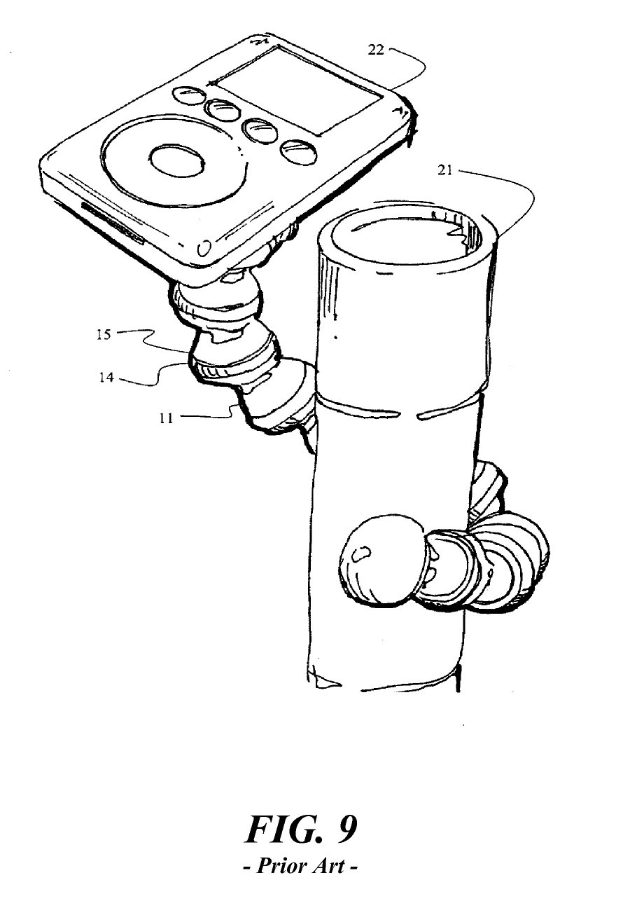

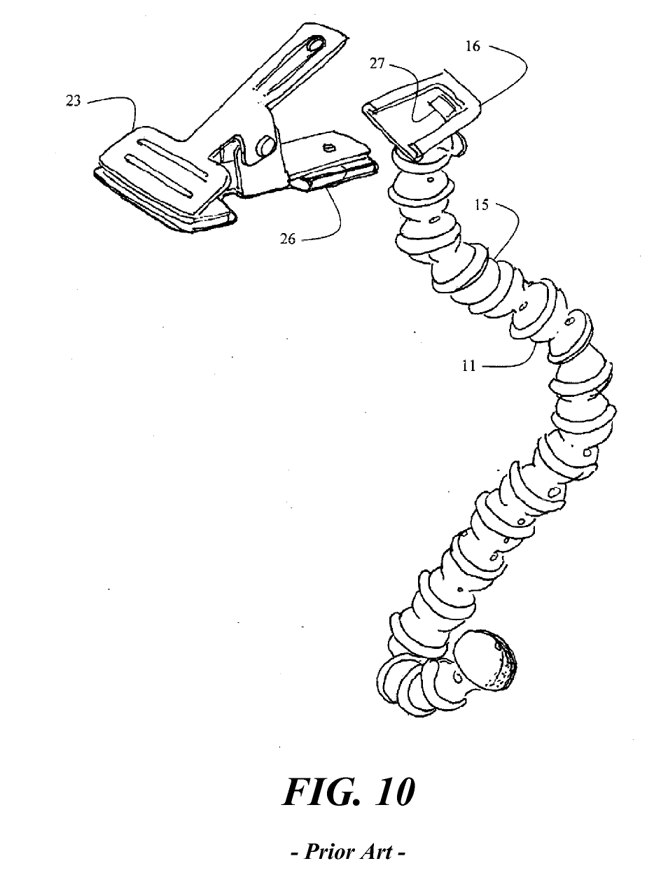

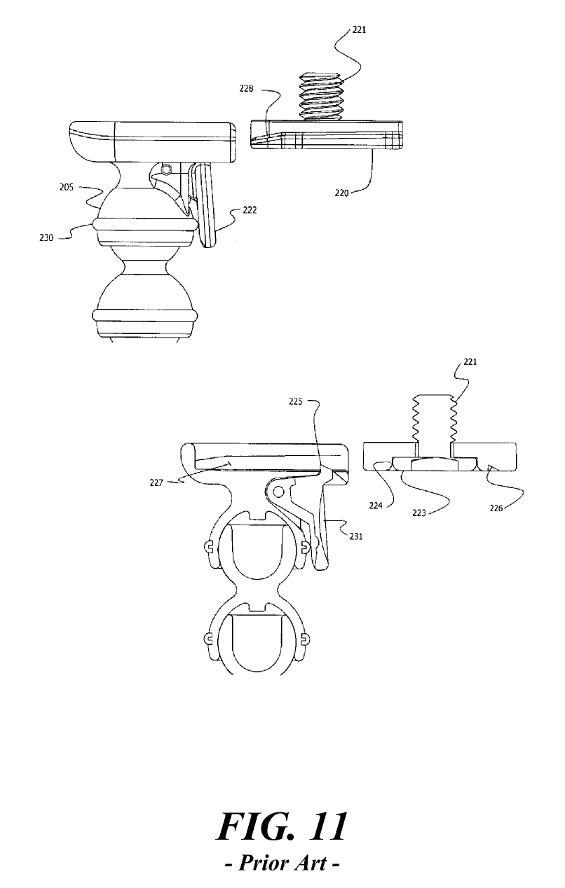

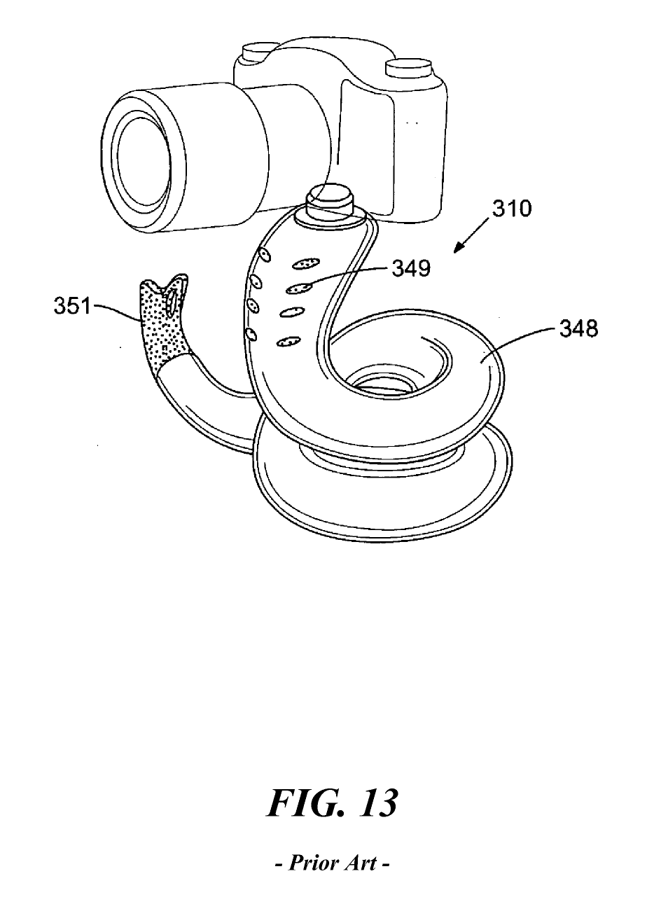

While the various devices depicted in FIGS. 1-13 may be suitable for their intended purposes, each of these devices also suffers from various infirmities. For example, conventional tripods of the type depicted in FIGS. 1-2 are bulky, and require too much set up time, to lend themselves well to regular consumer usage. The tripod of FIGS. 3-4 is limited in use to relatively flat surfaces, as is the monopod of FIG. 8. The miniature tripods of FIGS. 5-7, and the monopods of FIGS. 9-12, offer some flexibility, but their bending radii are limited by their multiple joint construction and hence are relatively small, thus limiting their use to certain types of substrates (the core of the device depicted in FIG. 13 has a similar jointed construction, and thus has similar limitations). In addition, the multiple joint construction of these devices may cause them to pinch the skin or clothing of the user.

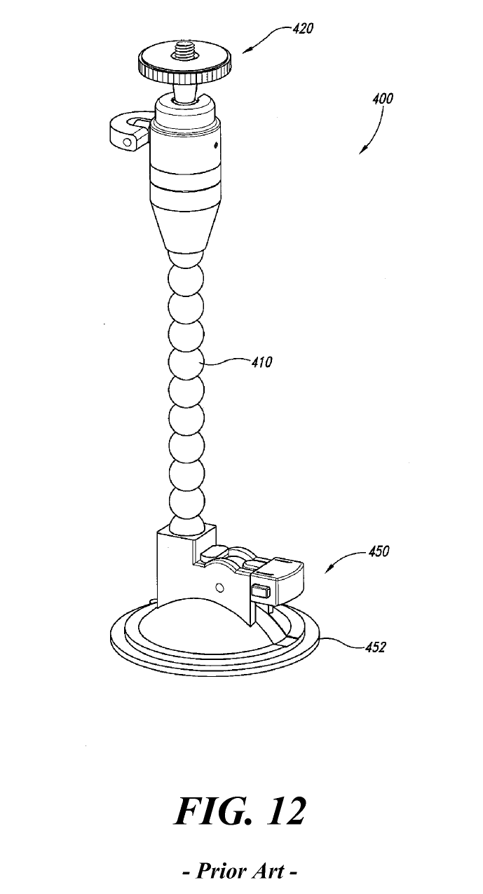

Moreover, some of these devices, as with the embodiment depicted in FIG. 9, lack the means to secure the device to the substrate, and thus cannot ensure that an attached imaging device will not slip or fall. Others, such as the device depicted in FIG. 12, address this issue, but are limited in use to certain types of substrates.

There is thus a need in the art for a platform for an imaging device, such as a camera or video recorder, which is portable, durable, highly flexible, and capable of maintaining an imaging device in a fixed orientation for a long period of time, and yet is simple and inexpensive in design. There is further a need in the art for such a device which can readily be adapted to allow an imaging device to be supported on a variety of surfaces, which can also function as a handgrip, and which can be utilized to extend the capabilities and improve the ease of use of conventional tripods and other platforms for imaging devices. These and other needs may be met by the devices and methodologies disclosed herein.

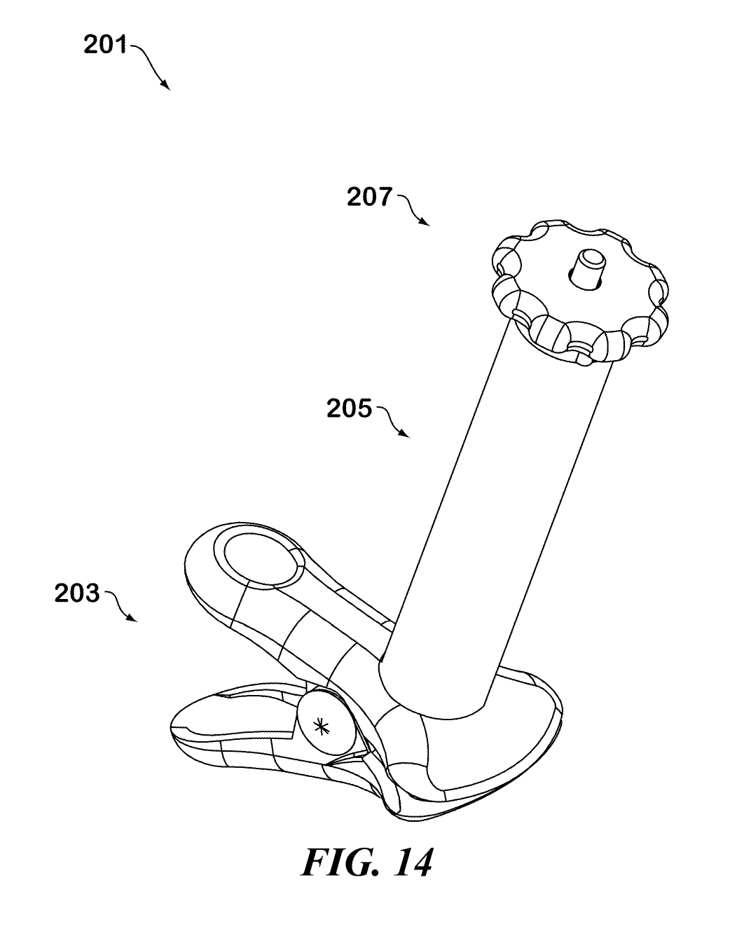

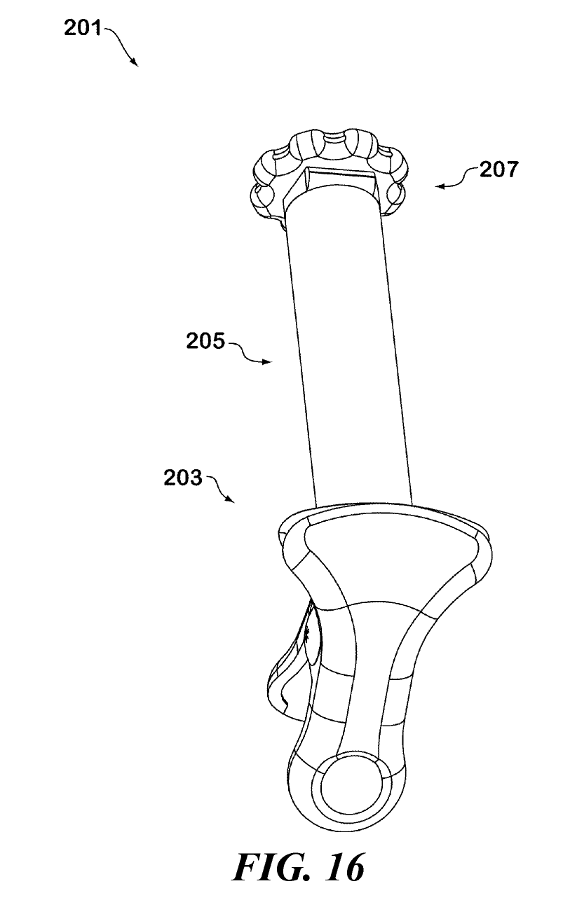

FIGS. 14-18 depict a first particular, non-limiting embodiment of a platform for an imaging device of the type disclosed herein. The platform 201 comprises a clip 203, a rigid, deformable arm 205 which extends from the clip 203, and a mount 207 which is adapted to be releasably attached to an imaging device (not shown).

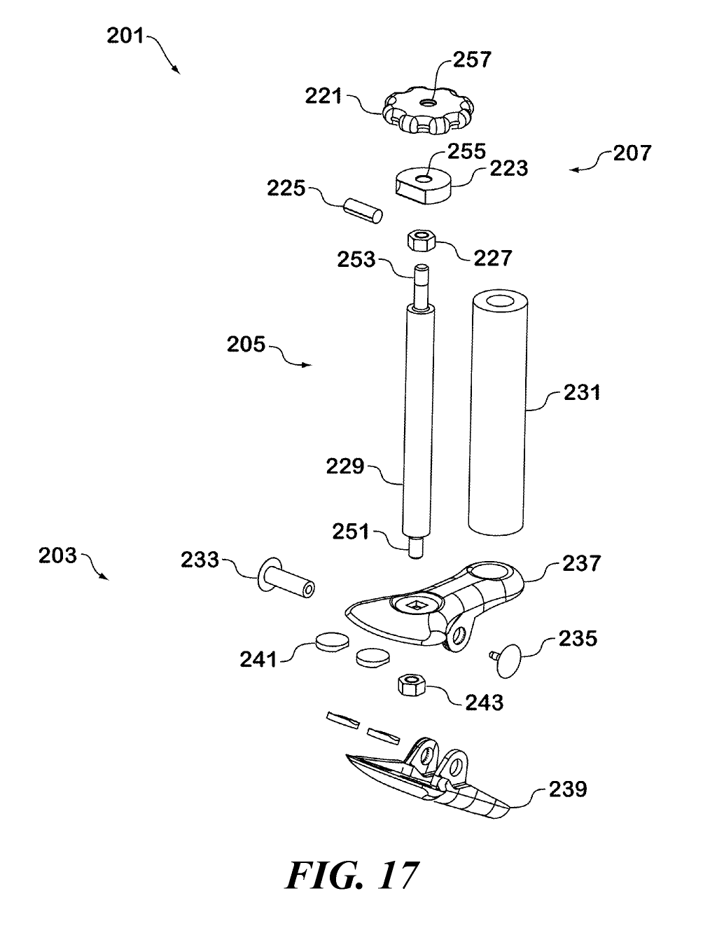

FIG. 17 shows the components of the platform 201. As seen therein, the mount 207 comprises a thumb wheel 221, a level cap 223, a mini-level 225 and a hex nut 227. The mini-level 225 in this embodiment is a simple bubble level which provides an indication of the horizontal alignment of the mount, though in other variations of this embodiment, other levels may be utilized which provide an indication of the alignment of the mount 207 in other directions. For example, a level may be utilized which indicates the horizontal and vertical alignment of the mount 207, or the alignment of the mount 207 along a plurality of axes.

The mini-level 225 is preferably seated in a complimentary shaped aperture provided in the level cap 223, though in some embodiments it may be incorporated into the thumb wheel 221 or into other components of the platform 201. Since the level cap 223 preferably comprises a slightly deformable material such as a stiff plastic, this construction allows the mini-level 225 to be easily snapped into place or removed through the use of moderate force, and yet holds the mini-level 225 securely in place during use. The construction of the level cap 223 also allows it to be rotated about the vertical axis of the mount so that the mini-level 225 can be made visible to the user without necessitating the user to adjust his position or to adjust the position of the platform 201 or the imaging device. Hence, the user can readily confirm the attitude of the mount 207 and imaging device at any time. By contrast, many prior art platforms either lack a level, or require the platform, the imaging device or the user to be oriented in a specific way so that the level is visible.

Referring again to FIG. 17, the deformable arm 205 comprises a core structural element 229 having a pliable foam casing 231 disposed thereon. The pliable foam casing 231 preferably comprises a foamed plastic or rubber and allows the arm 205 to be readily gripped by the user. This construction allows the platform 201 to be used as a handgrip in addition to its function as a monopod support platform. In such a use, the foam casing 231 may act as a vibration dampening device by effectively absorbing vibrations from the hand of the user so that these vibrations are not transferred to the imaging device. This may improve image quality and reduce image blur, especially in slow shutter speed situations.

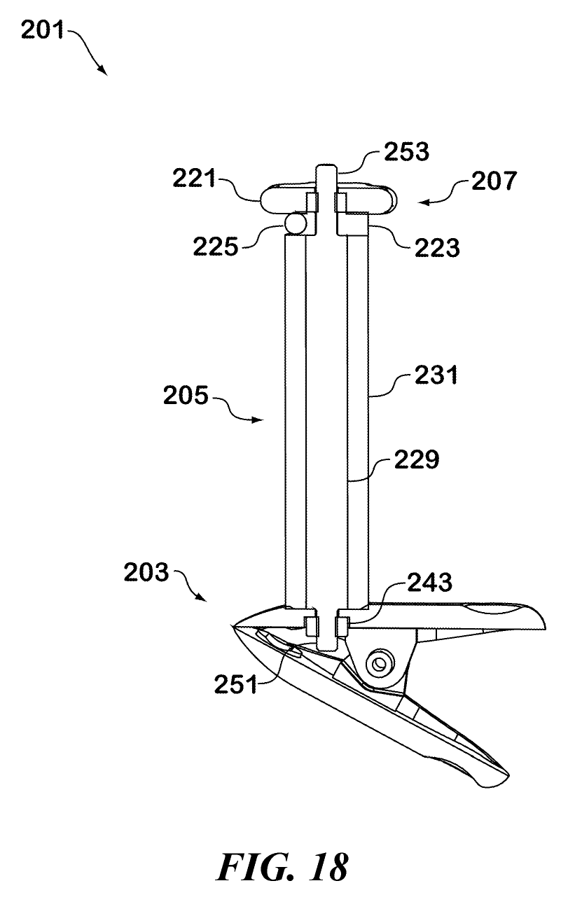

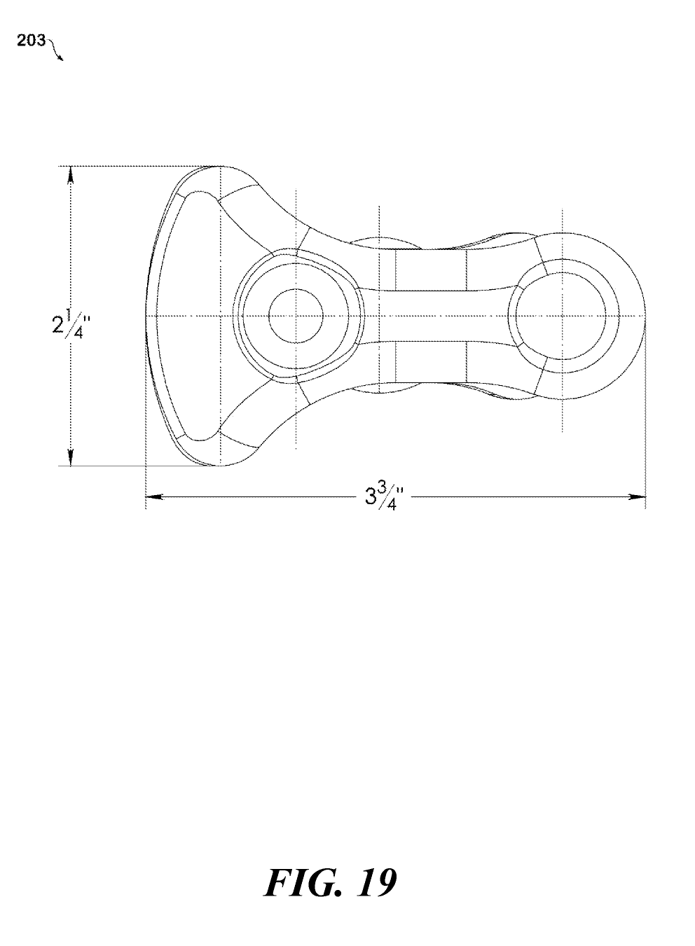

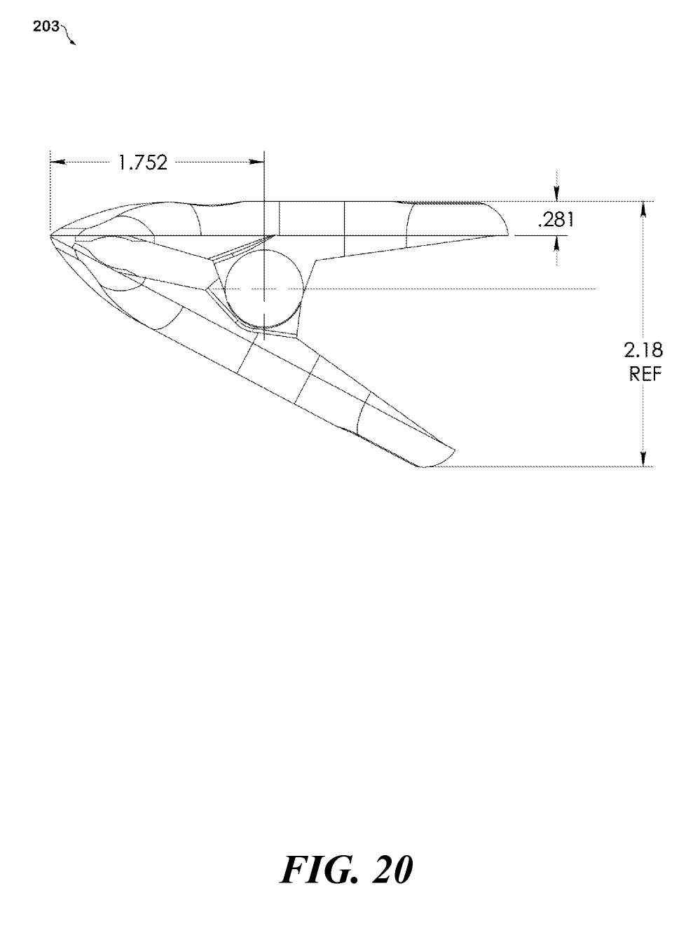

The core structural element 229 is attached on one end to the clip 203 by way of a nut 243 and a first threaded shaft 251 (see FIG. 18) that is set (preferably with the aid of an adhesive) in an aperture provided in one end of the core structural element 231. Of course, it will be appreciated that a variety of other suitable means as are known to the art may be utilized to attach or combine the elements of the platform 201.

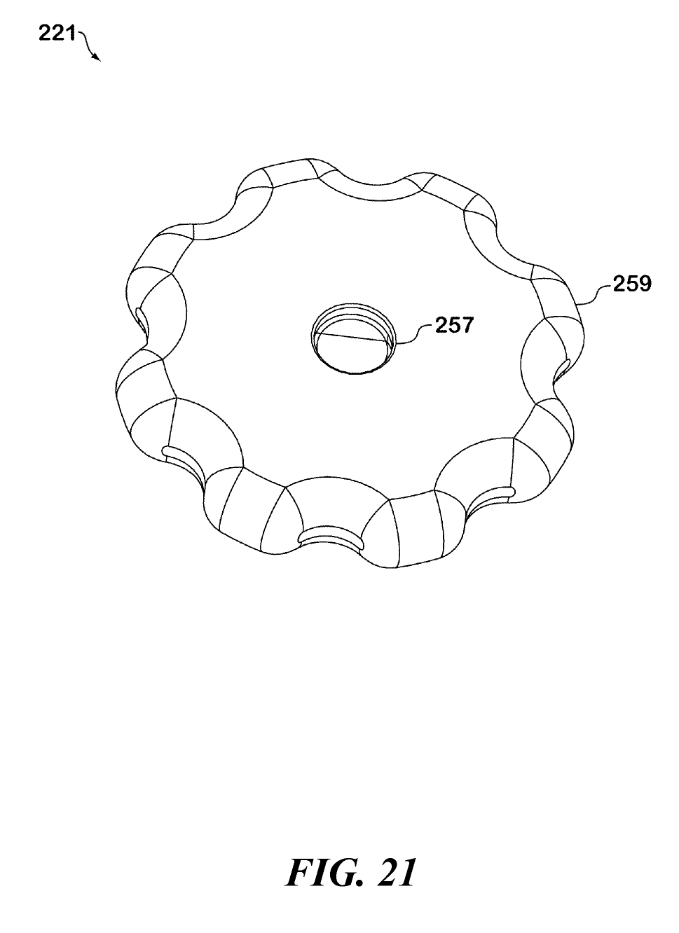

The core structural element 231 is equipped on the opposing end with a second threaded shaft 253 that rotatingly engages a hex nut 227 and a centrally disposed threaded aperture 257 provided in thumb wheel 221, and which also extends through a centrally disposed aperture 255 (which may, or may not, be threaded) provided in the level cap 223 (see FIG. 18). The second threaded shaft 253 also rotatingly engages a complimentary shaped threaded aperture provided on the body of an imaging device (not shown) or mount associated therewith. The thumb wheel 221 (shown in greater detail in FIG. 21) is preferably equipped with a scalloped surface to facilitate grip, and allows the attachment between the platform 201 and the imaging device to be quickly tightened or loosened. In particular, the thumb wheel 221 is preferably constructed so that it can be rapidly spun about its axis with a single flick of the thumb until it presses against the bottom of the imaging device, at which point it can be rotated further as needed to ensure a snug fit.

Still referring to FIG. 17, the clip 203 comprises opposing upper 237 and lower 239 clip elements which pivot around an axle formed by a pin post 233 and a pin insert 235. The axle may be equipped with a coil or spring to provide sufficient resistance so that the clip 203 can firmly grasp a substrate. The jaws of the clip 203 are equipped with a set of resilient pads 241, both to improve the grip of the clip jaws on surfaces, and to protect such surfaces from being damaged by the clip 203.

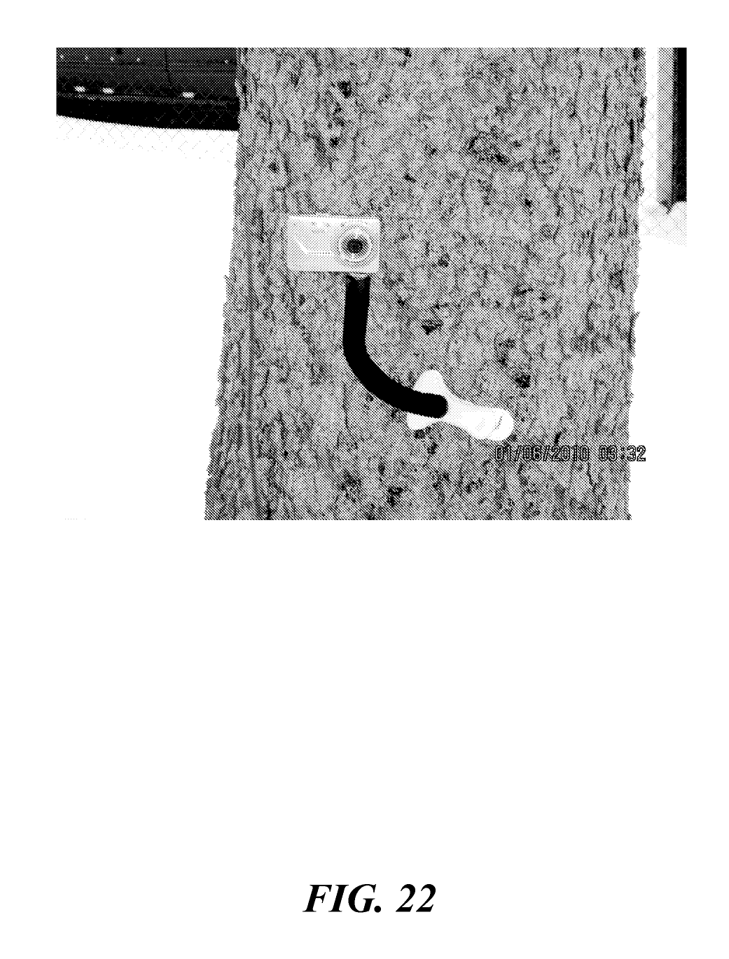

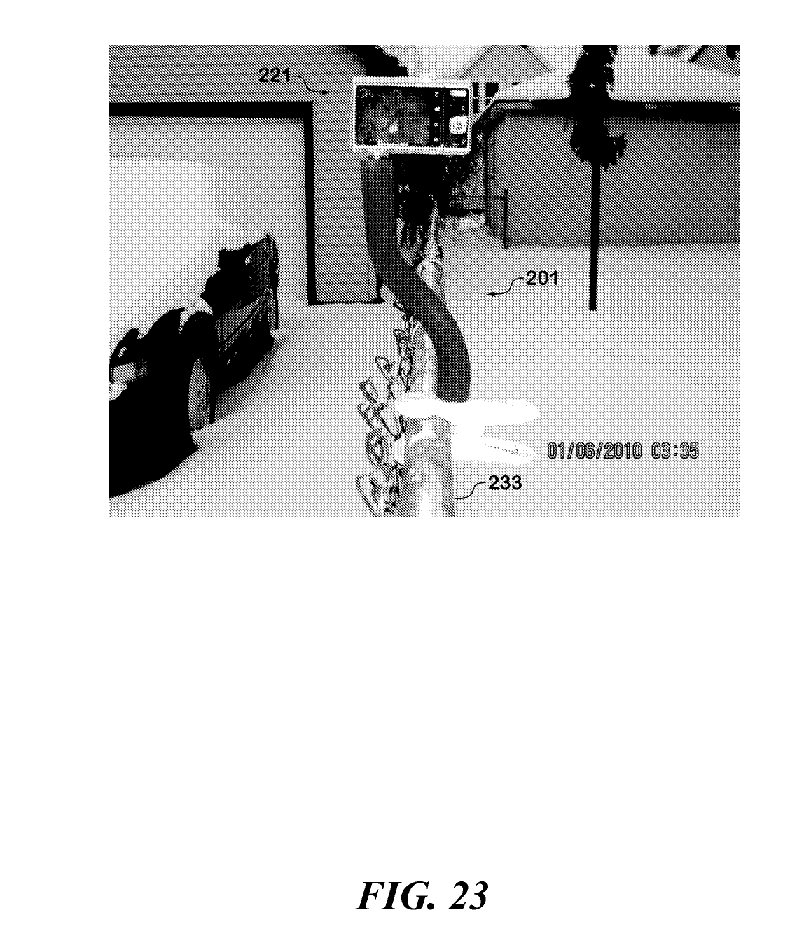

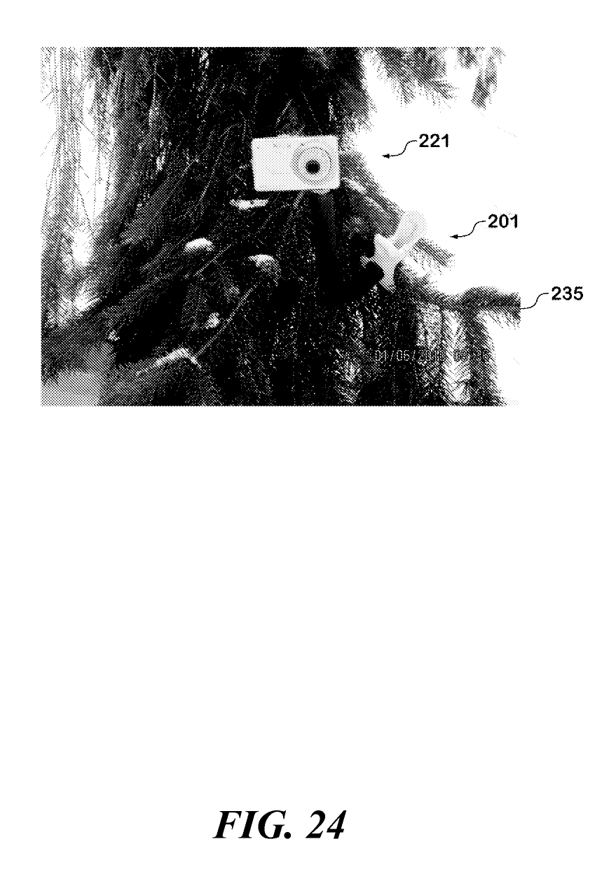

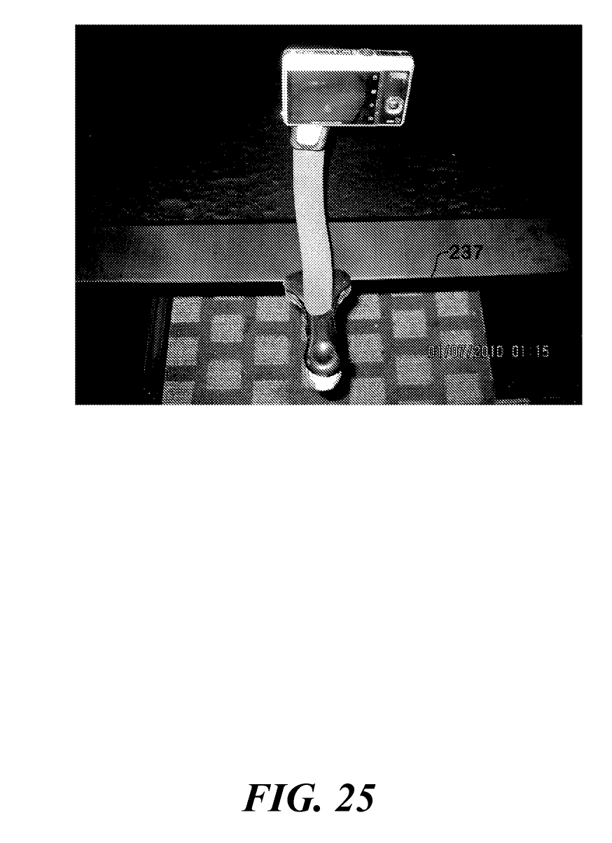

FIGS. 22-25 illustrate some uses in the field of the platform 201 of FIGS. 14-18 as a mount for an imaging device 221. In these particular examples, the imaging device 221 is a digital camera. Thus, FIG. 22 illustrates the use of the platform 201 to mount the imaging device 221 on the trunk of a tree 231. FIG. 23 illustrates the use of the platform 201 to mount the imaging device 221 on the rail 233 of a fence. FIG. 24 illustrates the use of the platform 201 to mount the imaging device 221 on the branches 235 of a tree. FIG. 25 illustrates the use of the platform 201 to mount the imaging device 221 on the edge of a table top 237.

In each of the applications depicted in FIGS. 22-25, after the imaging device 221 is mounted on the platform 201, the platform 201 is releasably attached to the respective substrate by way of the clip 203. The arm 205 of the platform 201 is then adjusted as necessary to achieve the desired orientation of the imaging device 221, after which the imaging device 221 is held steadily in position and can capture images without blurring.

It will be appreciated that the platform 201 allows the imaging device 221 to capture images at shutter speeds or apertures that might not be suitable for hand-held shooting. Moreover, the platform 201 allows the imaging device to be positioned for remote control (as through the use of wireless shutter activation), for use in gesture recognition activation mode (e.g., so that the imaging device is activated upon detection of a wink, smile, wave, or other such cue) or for timed shutter activation. This may be desirable for a variety of photographic or video capture situations as, for example, in wild life photography or where the person capturing the image wishes to be in the picture.

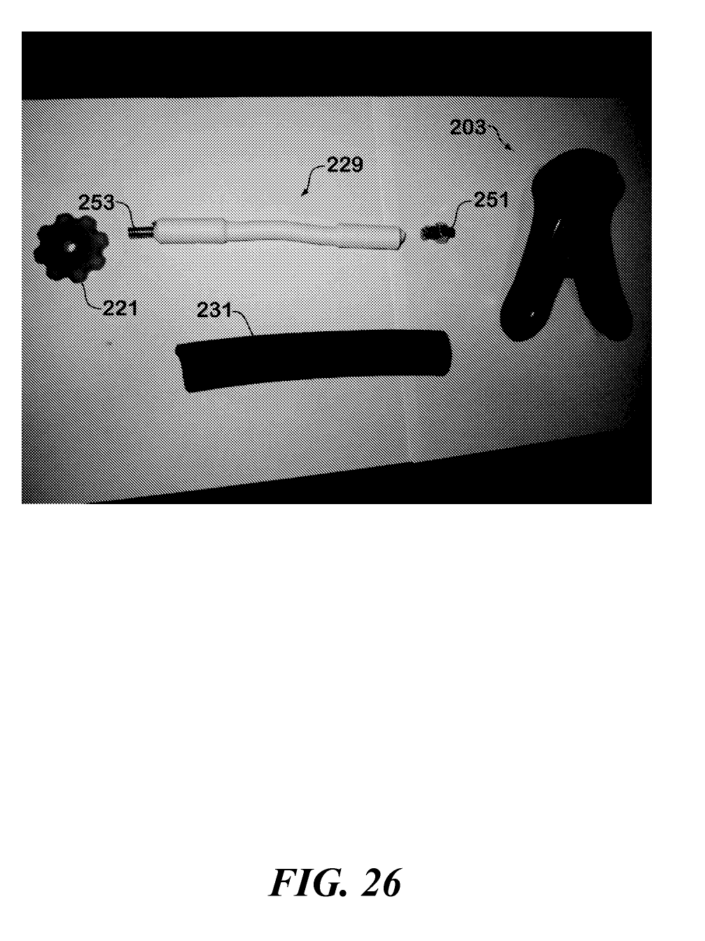

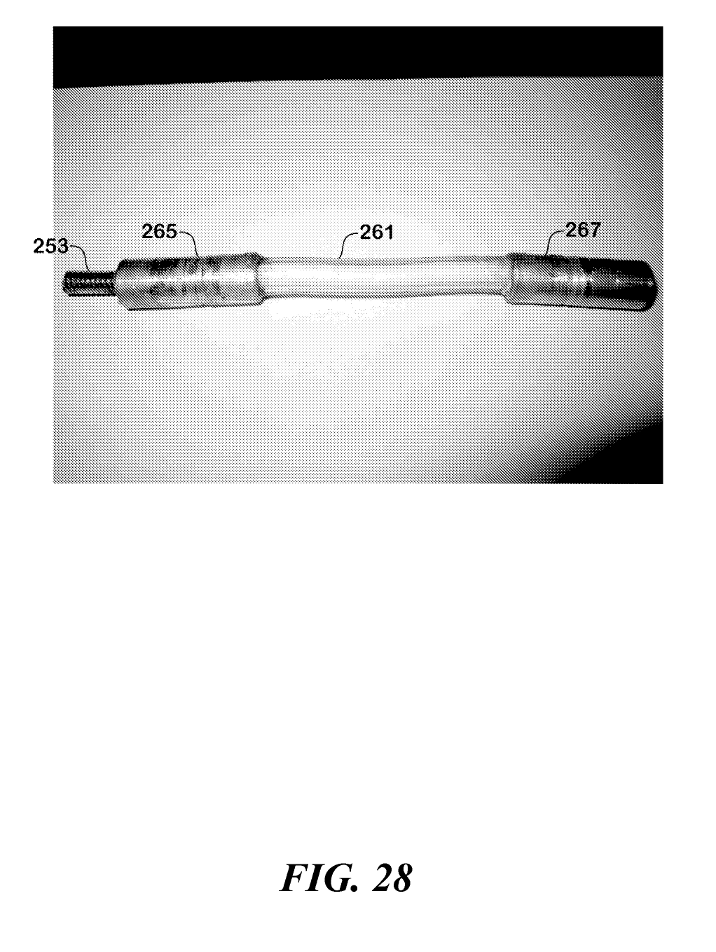

FIGS. 26-28 illustrate the details of the construction of the arm 205 in one particular, non-limiting embodiment of the platform 201 disclosed herein. FIG. 26 depicts the platform 201 in a disassembled state to show the core structural element 229. The second threaded shaft 253 is removed to show the details thereof.

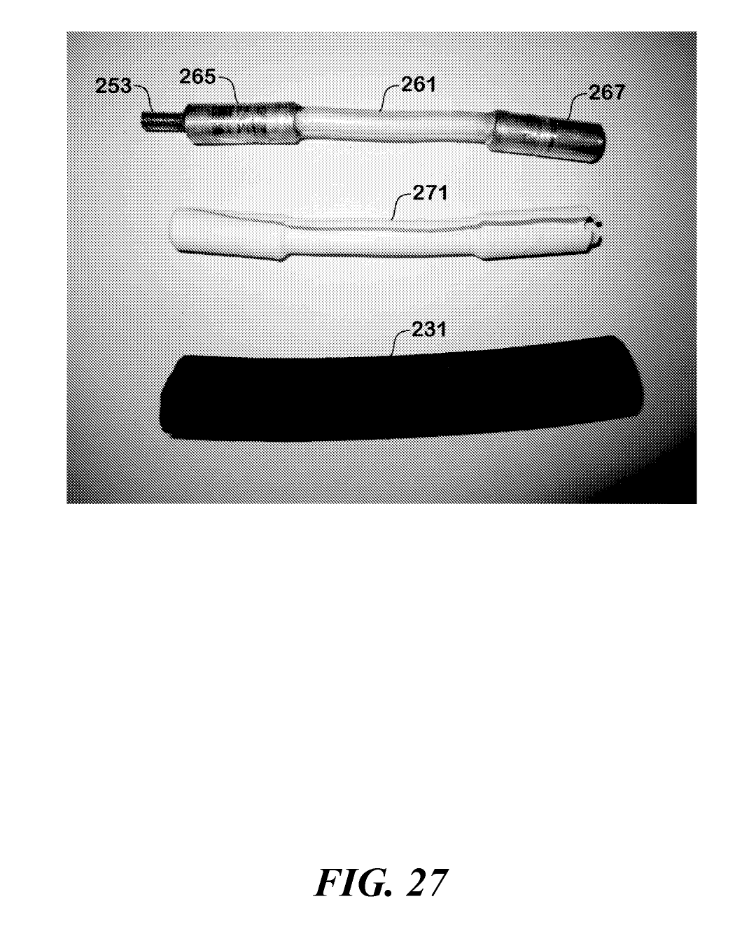

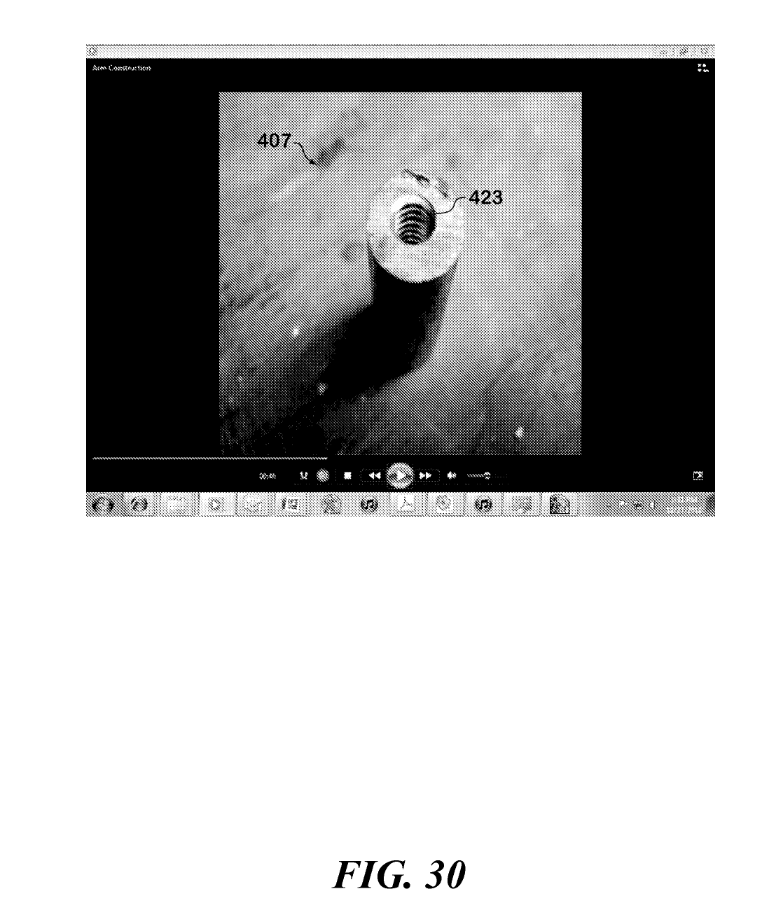

As seen in FIG. 27, the core structural element 229 comprises a flexible tube 261 which is filled with a particulate material, and which is capped, respectively, on first and second opposing ends with first 265 and second 267 end caps. The particulate material may be, for example, silica, titanium dioxide, aluminum oxide, or the like. This construction gives the arm its rigid yet flexible characteristics. The first end cap 265 is equipped with an aperture 269 adapted to accept the first threaded shaft 253 (this feature is depicted for a related embodiment in FIG. 30), and the second end cap 267 is equipped with a second threaded shaft 251. An adhesive seal is preferably applied where the first 265 and second 267 end caps interface with the flexible tube 261.

The core structural element 229 is also equipped with a sheathing 271, which preferably comprises a material having a low coefficient of friction such as, for example, polyfluoroethylene or a vinyl plastic. The sheathing 271 may be applied in the form of a film (which may be a shrink wrap film), coating or tape, or in another suitable form. The sheathing 271 allows the core structural element 229 to be more easily inserted into the foam casing 231.

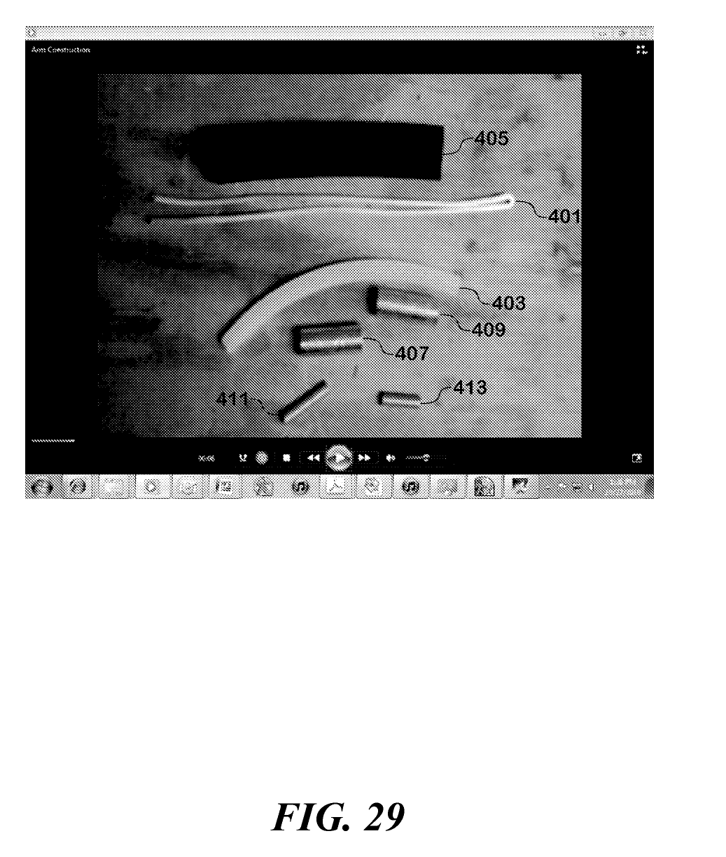

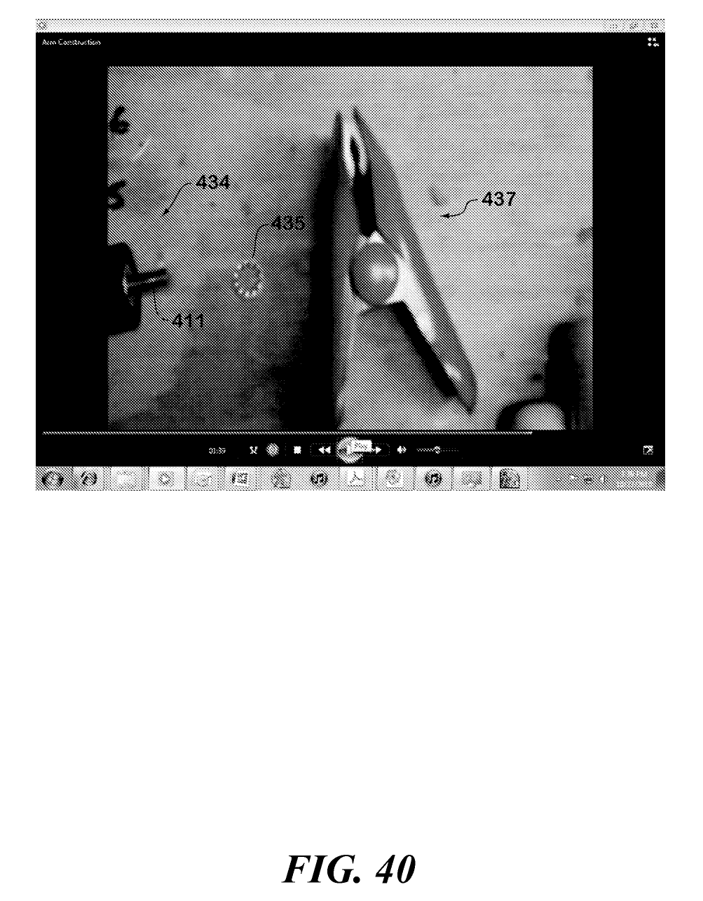

FIGS. 29-46 illustrate a particular, non-limiting embodiment of a methodology for making a second, preferred embodiment of a monopod of the type depicted in FIG. 14. The monopod in this embodiment differs from the embodiment depicted in FIGS. 26-28 in the construction of the core structural element, but is otherwise identical or similar.

As seen in FIG. 29, the monopod built in accordance with this particular method is assembled from a portion of number #13 caliber wire 401, an inner sheath 403 which houses the wire 401 (and which, in this particular embodiment, comprises a portion of flexible plastic tubing), an outer sheath 405 which comprises a foamed polymeric material and which is disposed about the inner sheath 403, first 407 and second 409 end caps, and first 411 and second 413 threaded connectors. It will be appreciated that wire 401 may be of varying caliper, and that the desired caliper may be dictated by the intended end use.

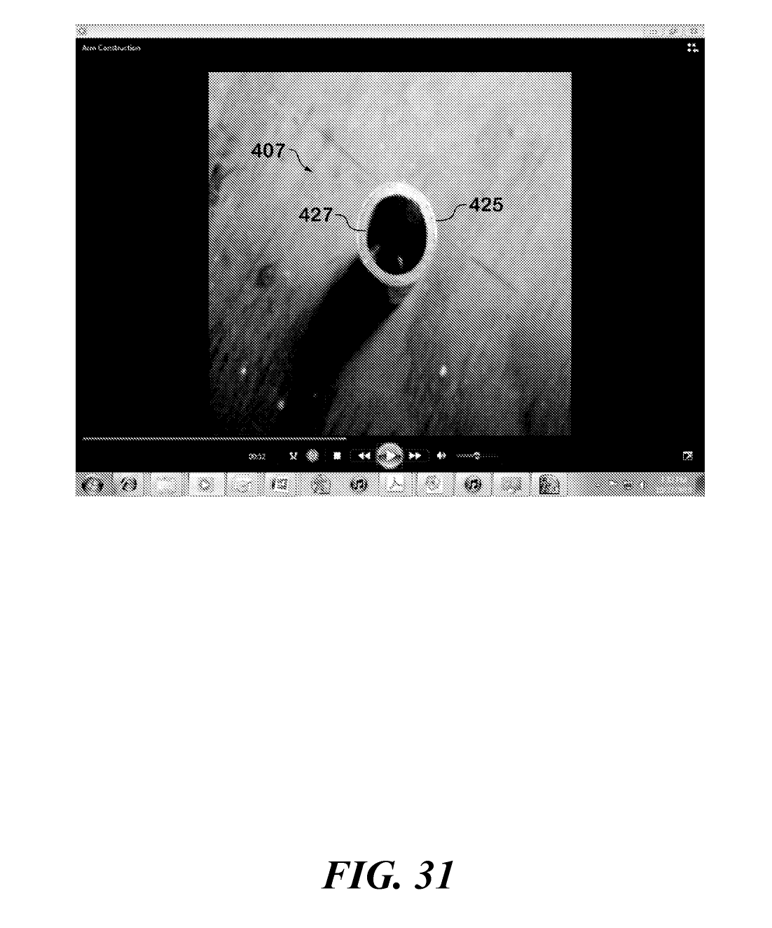

The details of the end caps 407, 409, which are preferably identical, may be appreciated with respect to FIGS. 30 and 31. As seen therein, each of the end caps 407, 409 comprises a first end 421 having a threaded receptacle 423 defined therein (see FIG. 30) and a second end 425 equipped with a concave receptacle 427 (see FIG. 31).

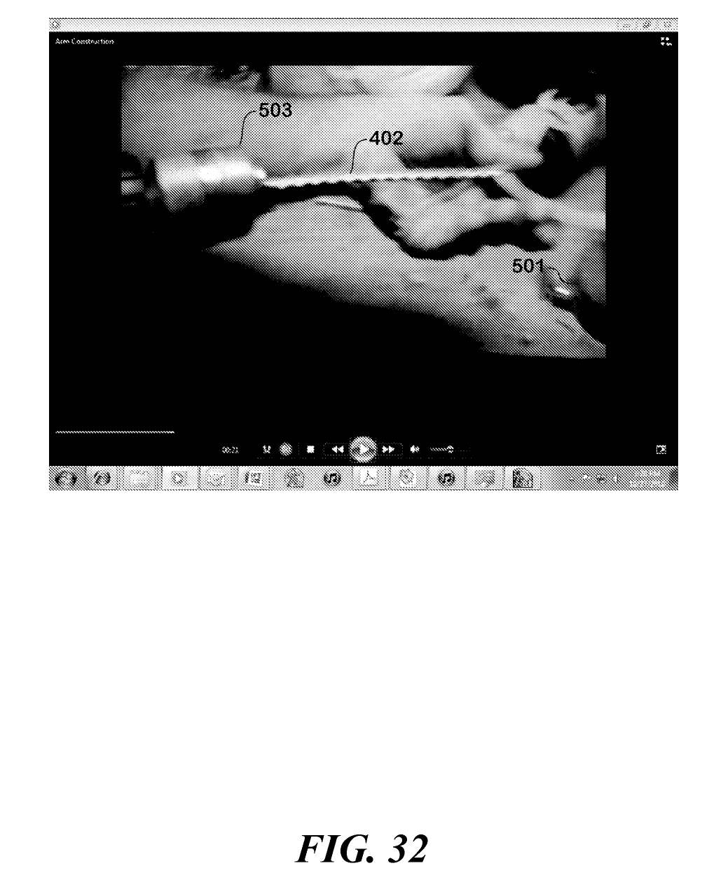

The manner in which the monopod may be assembled in accordance with this embodiment may be appreciated with respect to FIGS. 32-45. As seen in FIG. 29, the wire 401 is initially folded into a U-shape. The folded wire 401 may then be twisted about its axis to form a braided wire 402. Such braiding may be accomplished, for example, by placing a first end of the folded wire 401 into a vice clamp 501 and twisting the second, opposing end about its longitudinal axis. This may be accomplished, for example, by inserting the second end of the folded wire 401 into a drill chuck 503, and then activating the drill.

Of course, it will be appreciated that various other means may be utilized to accomplish braiding of the wire 401, and that the devices and methodologies described herein are not necessarily limited to any particular approach. For example, in some embodiments, a long strand of braided wire may be formed by a suitable means as is known to the art, and the braided wire may then be cut into portions of desired length as, for example, through the use of a guillotine chopper. It will also be appreciated that the braided wire may be formed from any suitable number of individual wire strands of any desired caliper. Typically, the number of strands and the caliper of those strands will be selected to obtain a suitable degree of rigidity and deformability in the final construction as is deemed suitable for the contemplated end use of the device.

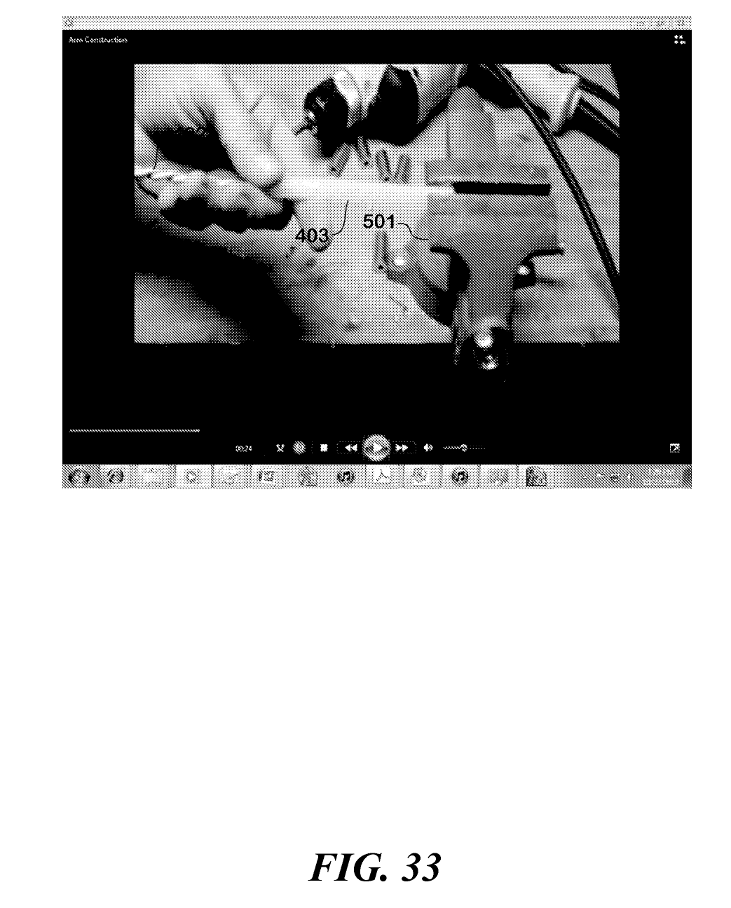

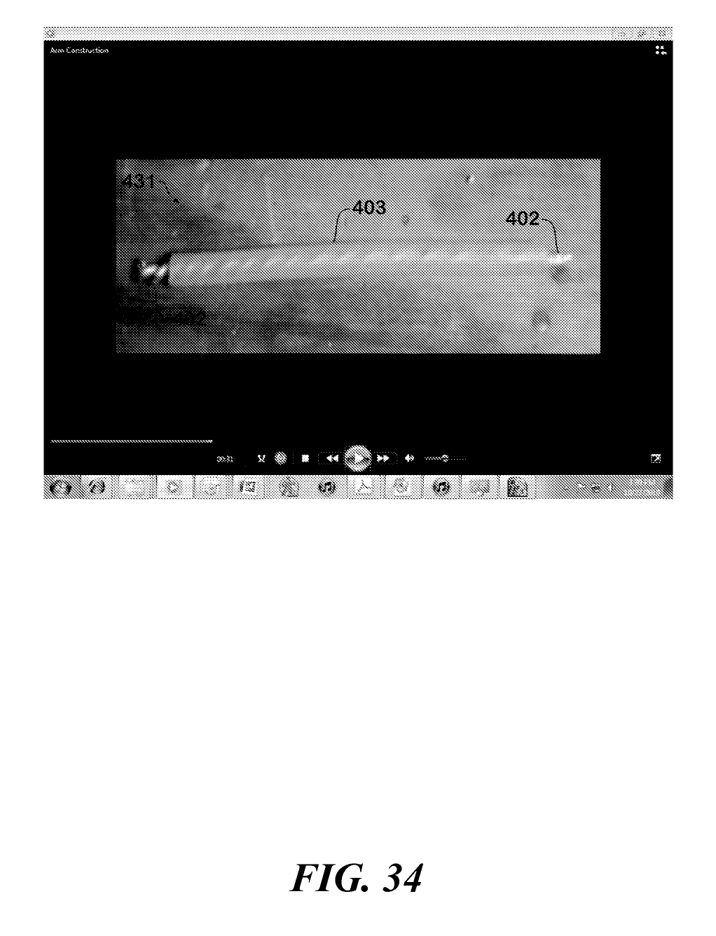

As seen in FIG. 32, the second end of the braided wire 402 is then removed from the vice clamp and inserted into the inner sheath 403. The opposing end of the inner sheath 403 is held in place during this process with a vice clamp 501 as shown in FIG. 33. The drill 503 is then activated, which causes the braided wire 402 to advance along the length of the inner sheath 403 until it protrudes from the opposite side. The resulting construct is then removed from the drill chuck 503 and the joined ends of the braided wire 402 are clipped, thus yielding the sheathed wire 431 depicted in FIG. 34 in which a portion of the braided wire 402 protrudes from each end of the inner sheath 403.

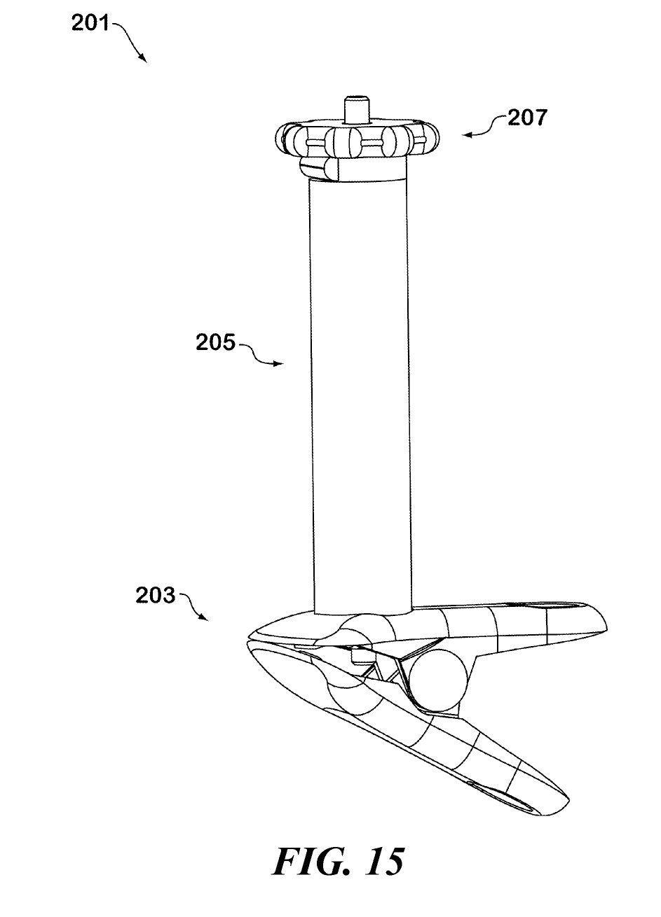

Various other approaches may be utilized to create the sheathed wire 431. For example, in some embodiments, the inner sheath 403 may have a suitable inner diameter to allow the braided wire 402 to be readily inserted into the inner sheath 403. In other embodiments, the inner sheath 403 may be applied as a shrink wrap article, a curable coating (which may be cured, for example, through thermal curing or exposure to radiation), or the like. The inner sheath 403 is preferably sufficiently flexible to allow the arm 205 (see FIG. 15) of the resulting platform 201 to be manipulated into any desired orientation, and yet is preferably sufficiently rigid to distribute the bend radius over a sufficient surface area of the braided wire 402 so that the braided wire 402 is sufficiently resistant to mechanical fatigue.

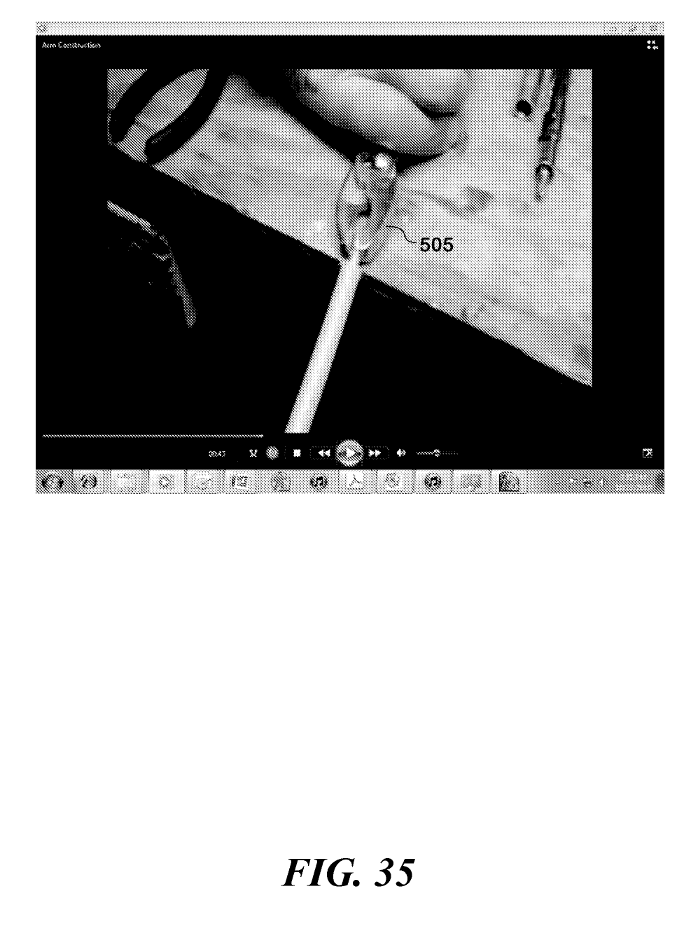

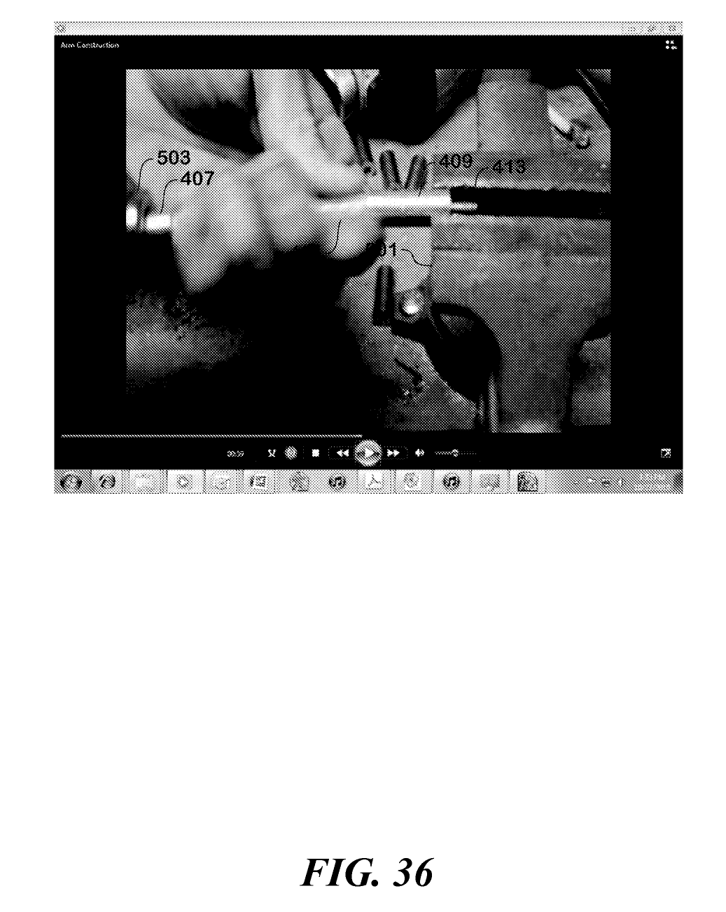

As shown in FIGS. 35-36, the concave receptacle 427 (see FIG. 31) of the first end cap 407 is then twisted onto a first end of the sheathed wire 431. The opposing end of the sheathed wire 431 may be held in place with a pair of pliers 505 during this process as shown in FIG. 35. The outer diameter of the inner sheath 403 is preferably chosen to be just slightly smaller than the inner diameter of the concave receptacle 427 so as to ensure a snug fit. Similarly, the inner diameter of the threaded receptacle 423 is preferably chosen to be just slightly larger than the outer diameter of the braided wire 402 so that it will rotatingly engage the second end of the braided wire 402 when it is inserted into the concave receptacle 427 and twisted. The first threaded connector 411 may be screwed into the threaded receptacle 423 of the first end cap 407 either before or after this step.

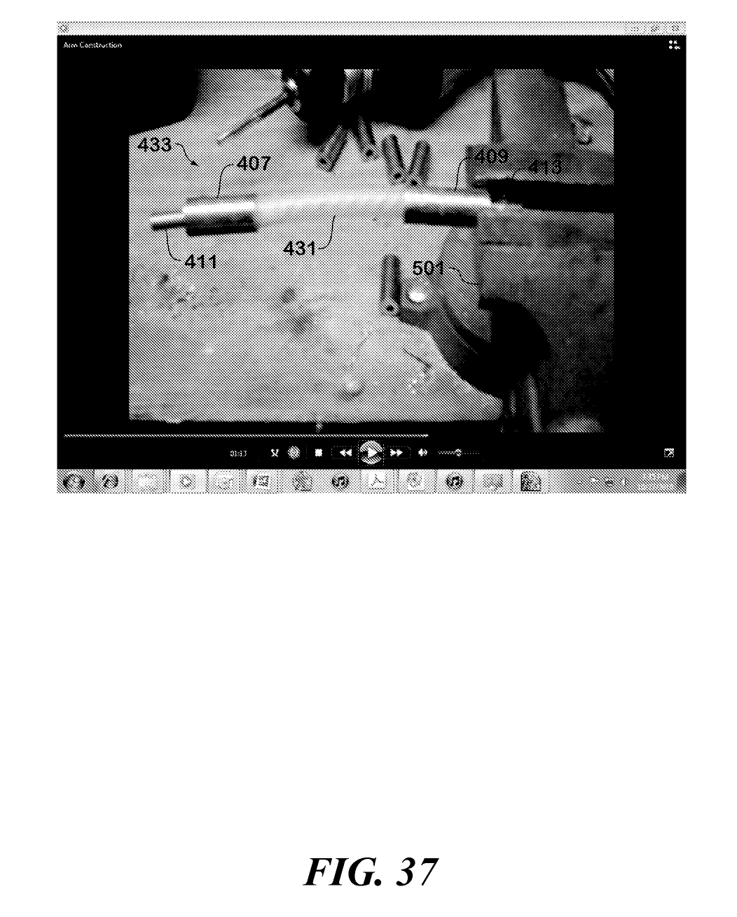

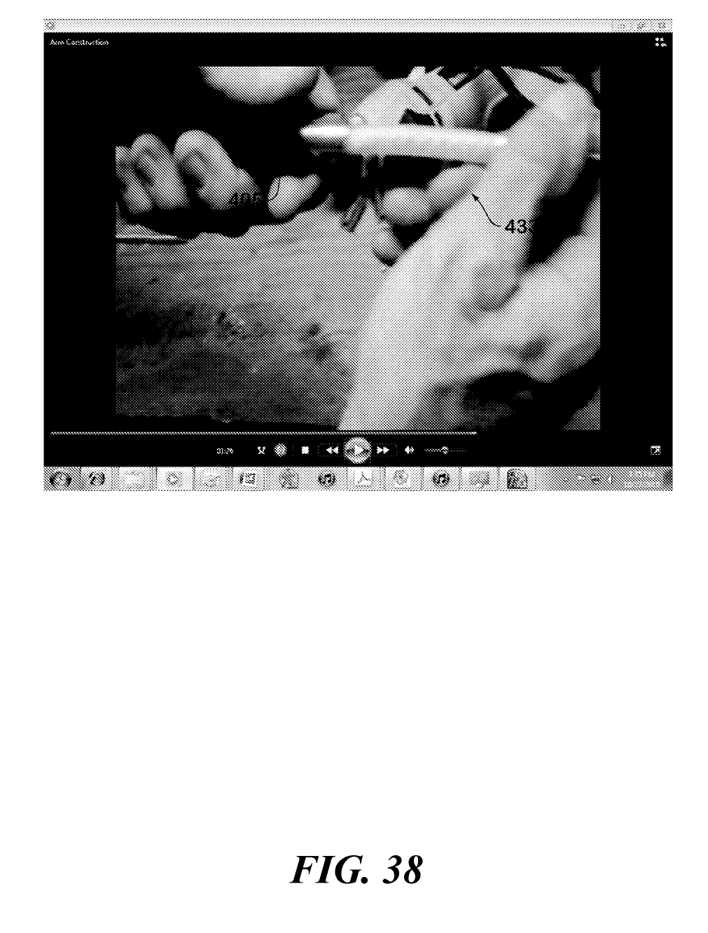

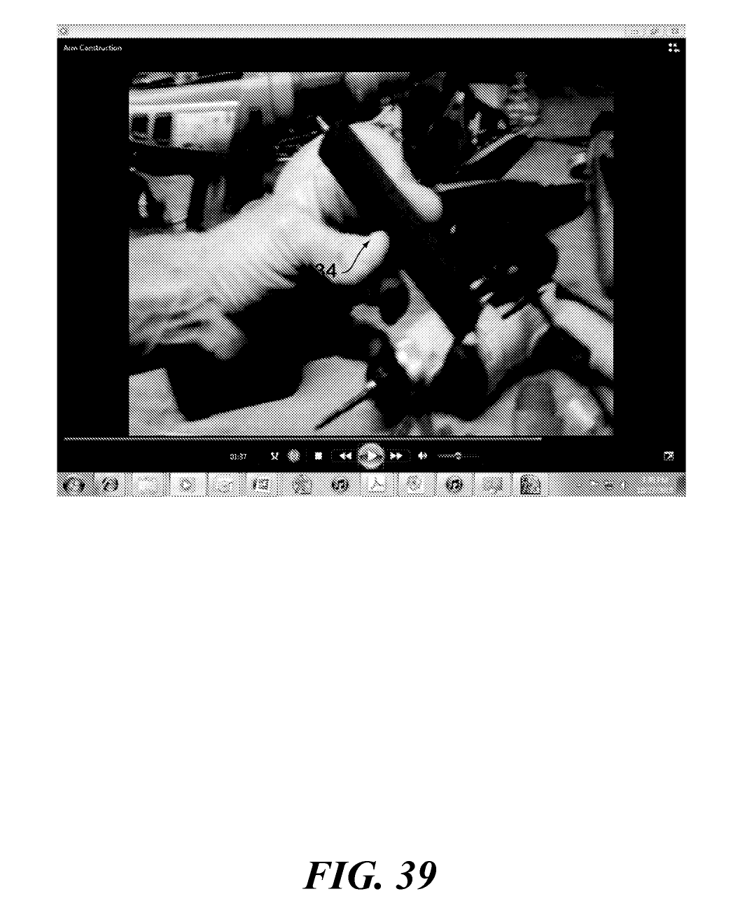

The first end cap 407 is then inserted into a drill chuck 503, and the drill is activated so that the opposing end of the sheathed wire 431 rotatingly engages the second end cap 409. The second end cap 409 may be held in place during this process by holding it in a vice clamp 501, as illustrated in FIG. 36 (the second threaded connector 413 may be inserted in the threaded receptacle of the second end cap 409 either before or after this step). The resulting article, which will form the rigid, yet flexible, backbone 433 of the monopod, is depicted in FIG. 37. The outer sheathing 405 is slid over the backbone 433, as shown in FIG. 38. The resulting sheathed backbone 434 is shown in FIG. 39.

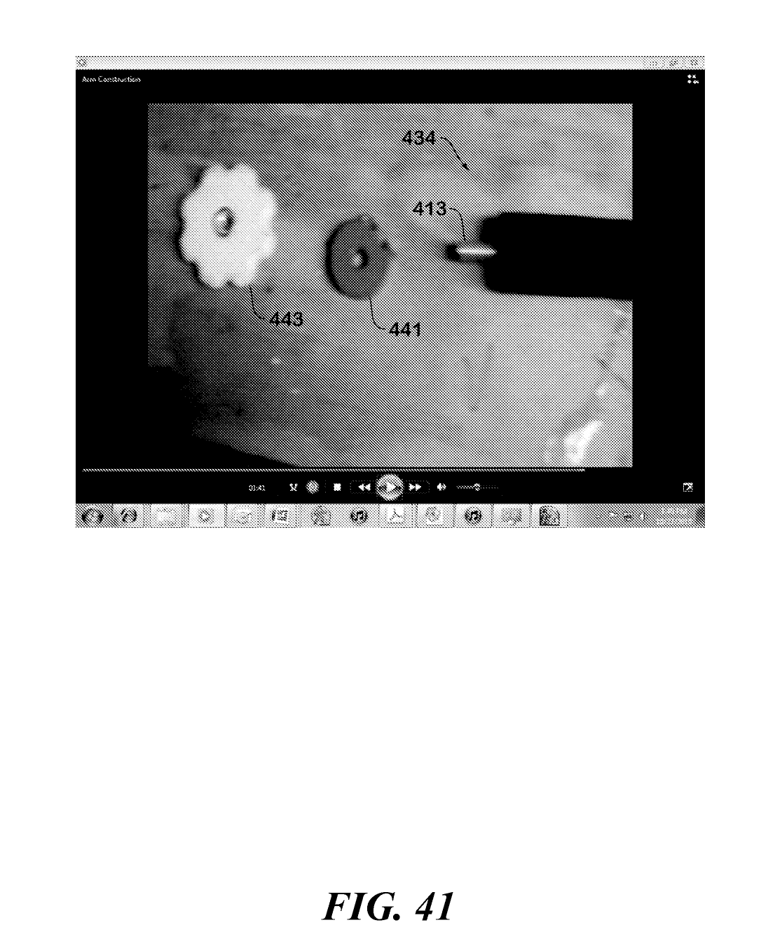

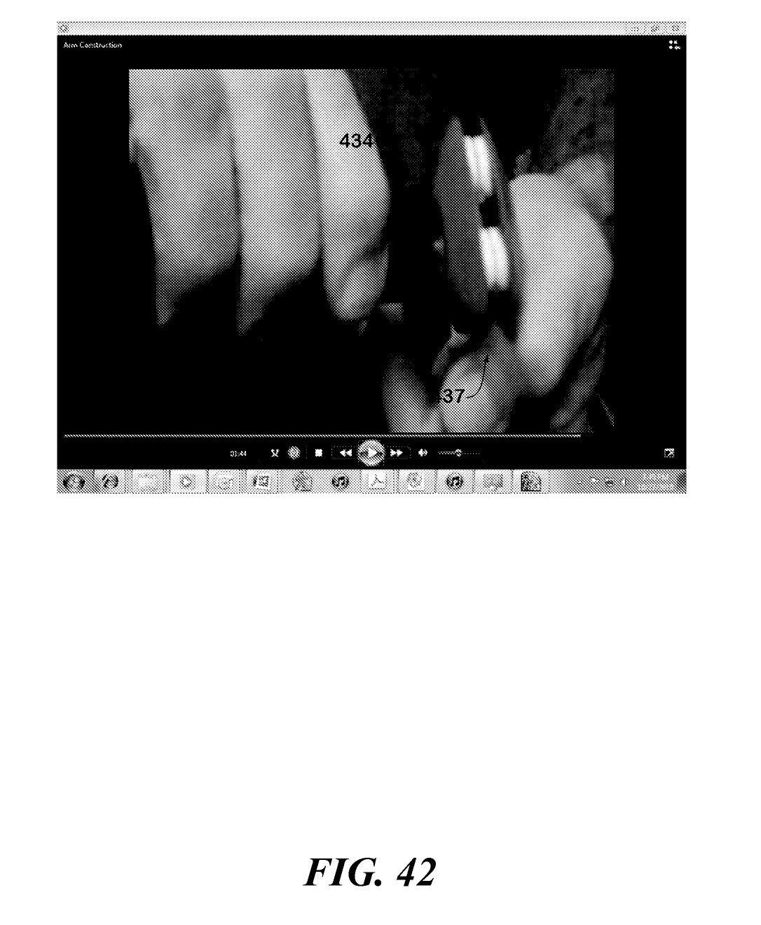

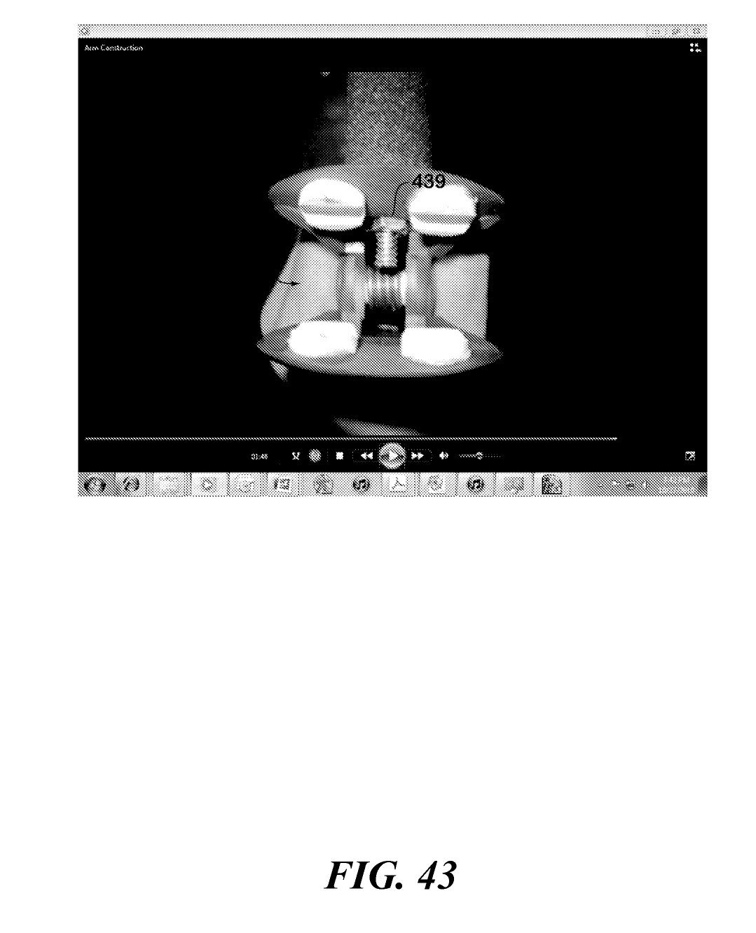

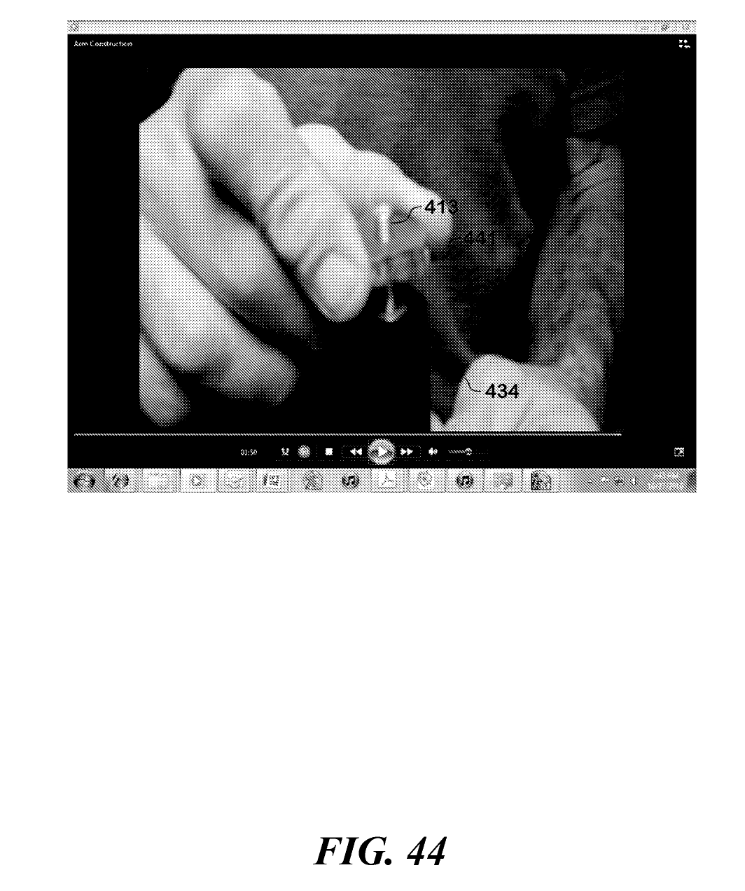

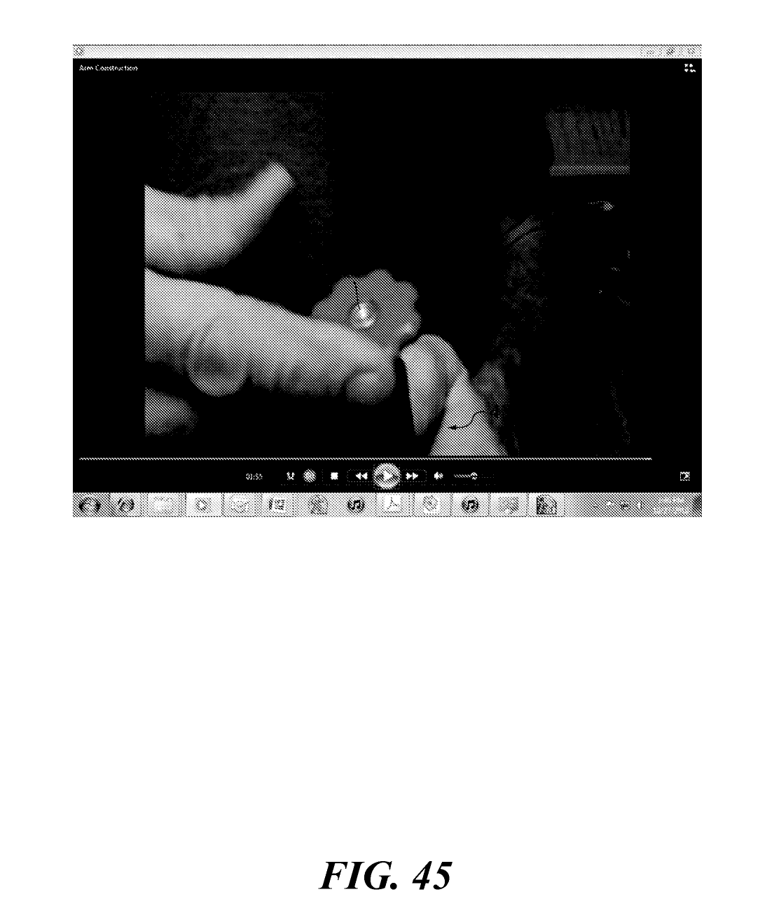

As shown in 40, a toothed washer 435 and clamp 437 are secured to the first threaded connector 411 on the sheathed backbone 434. This is accomplished by inserting the first threaded connector 411 into an aperture provided in the clamp 437 and securing it there with a hex nut 439, as illustrated in FIGS. 42-43. As shown in FIGS. 41, 44 and 45, an annular level 441 is then placed over the second threaded connector 413 as shown in FIG. 44. The level 441 is secured in place with a thumb wheel 443 which rotatingly engages the second threaded connector 413 as shown in FIG. 45. The completed monopod is of the type depicted in FIG. 14.

Several variations are possible with the devices disclosed herein. By way of example, as seen in FIG. 18, the core structural element 229 is equipped with first 251 and second 253 threaded shafts. These shafts allow the arm 205 to be connected or interfaced with a wide variety of devices. For example, the clip 203 can be replaced with a variety of stands or adapters which allow the monopod 201 to be mounted on various surfaces. Such stands or adapters may have a first surface equipped with a threaded aperture adapted to rotatingly receive the first threaded shaft, and a second surface adapted to allow the monopod to attach to, stand upon, or interface with a desired substrate.

As a specific example of the foregoing, the first threaded shaft 251 may be attached to a conventional camera tripod, and the second threaded shaft 253 may then be attached to an imaging device. This arrangement can be used to effectively add height to the tripod. This arrangement also allows the imaging device to be quickly leveled even if the tripod itself is not leveled.

Moreover, this arrangement allows the attitude of the imaging device to be modified much faster, and with fewer hands, than is typically possible by changing the tripod settings. In particular, a conventional tripod is equipped with three adjustment mechanisms to allow the user to adjust the orientation of the tripod mount along three (typically mutually perpendicular) axes; hence, it is often necessary for each of these adjustment mechanisms to be adjusted in order to achieve a desired orientation. Moreover, adjustment of one of the adjustment mechanisms may require the further adjustment of another adjustment mechanism, especially when the tripod is not disposed on a flat surface. However, the combination of a conventional tripod with the platform described herein allows the user to quickly change the orientation of the imaging device with one hand. This allows the user to respond much faster to changes in image capture settings than is possible with a conventional tripod, and thus results in fewer missed opportunities for capturing images.

It will also be appreciated that the first threaded shaft 253 can be attached to objects other than imaging devices. For example, many photographic settings require lighting gear or supplements. Such gear can be mounted on a monopod of the type disclosed herein in a manner analogous to the mounting of an imaging device to provide lighting whose attitude may be quickly adjusted. The monopod may be utilized to support a variety of other such devices in an analogous manner including, for example, fans, radar detectors, lasers, UV curing guns, hair dryers, and the like.

It will further be appreciated that various adapters or kits may be provided to allow the monopods disclosed herein to interface with other objects having other means of attachment beyond the standard threaded aperture common in imaging devices. Such adapters may be the same as, or similar to, the adapters described above which are used to mount the monopod of various substrates, and will typically have a first surface equipped with a threaded aperture adapted to rotatingly receive the second threaded shaft 253, and a second surface adapted to allow the monopod to attach to a desired device or surface. As a particular non-limiting example, such an adapter may be provided to allow the monopod to attach to a device having a proprietary interface.

Embodiments are also possible in accordance with the teachings herein which allow the monopod to be connected or interfaced with a wide variety of devices without removing the clip 203. For example, the lower surface of the clip 203 can be equipped with a threaded aperture or other suitable attaching means which allows the clip to be attached to a variety of stands or adapters, thus allowing the monopod 201 (with the clip 203 attached) to be mounted on various surfaces. Such stands or adapters may, for example, have a first surface equipped with a threaded protrusion adapted to rotatingly engage the threaded aperture in the lower surface of the clip 203, and a second surface adapted to allow the monopod to attach to, or stand upon, a desired substrate.

As a specific example of the foregoing, a spike may be provided with a threaded protrusion on a surface thereof which is adapted to interface with the threaded receptacle on the bottom of the clip 203. Such a spike may be utilized, for example, to mount the monopod on the ground at an athletic event. A similar embodiment is possible in which the spike is equipped with a threaded aperture which can rotatingly engage the first threaded shaft 251, in which case the clip 203 can be removed and the monopod may be used in a similar manner.

Alternatively (or in addition), a stand or adapter may be equipped with a surface adapted to securely engage the jaws of the clip 203. For example, the stand or adapter may be equipped with a protrusion the clip 203 can attach to. This protrusion may be angled appropriately so that the upper surface of the clip 203 is level after attachment.

It will further be appreciated that various adapters or kits may be provided to allow the monopods disclosed herein to interface with other objects having other means of attachment beyond the standard threaded aperture common in imaging devices. Such adapters may be the same as, or similar to, the adapters described above which are used to mount the monopod of various substrates, and will typically have a first surface equipped with a threaded aperture adapted to rotatingly receive the second threaded shaft 253, and a second surface adapted to allow the monopod to attach to a desired device or surface.

As one particular, non-limiting example, such an adapter may be provided to allow the monopod to attach to a device having a proprietary interface. As another particular, non-limiting example, such an adapter may couple with the first 411 or second 413 threaded protrusion to provide a female interface (such as a threaded aperture). As yet another particular, non-limiting example, such an adapter may allow multiple arms 205 (see FIG. 15) of the type described herein to be coupled together in an end-to-end fashion to increase the overall length of the platform 201.

Various imaging devices may be utilized with the devices and methodologies disclosed herein. These include, without limitation, digital and conventional (film-based) cameras, video recorders, personal digital assistants (PDAs) with imaging capabilities, cellular or mobile phones with imaging capabilities, and computational devices with imaging capabilities.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

A1. A platform for an imaging device, comprising:
a first mount which releasably attaches to a substrate;
a second mount which releasably attaches to an imaging device; and
a rigid, deformable arm having a first end which is attached to said first mount and having a second end which is attached to said second mount, wherein said arm comprises a particulate mass disposed within a flexible enclosure.

A2. The platform of claim A1, wherein said particulate mass is tightly packed within said enclosure.

A3. The platform of claim A1, wherein said particulate mass is a free flowing mass prior to being disposed in said enclosure.

A4. The platform of claim A1, wherein said particulate mass comprises a material selected from the group consisting of silica, sand, aluminum oxide and titanium oxide.

A5. The platform of claim A1, wherein said enclosure is a tube.

A6. The platform of claim A4, wherein said tube is an elastomeric tube.

A7. The platform of claim A5, wherein said tube terminates on a first end in a first connector having an aperture defined therein.

A8. The platform of claim A5, wherein said tube terminates on a second end in a second connector having a threaded protrusion disposed thereon.

A9. The platform of claim A7, further comprising a fastener which fastens said first connector to said clip.

A10. The platform of claim A9, wherein said fastener comprises a threaded post which is insertable into the aperture of the first connector, and a nut which rotatingly engages said threaded post.

A11. The platform of claim A8, wherein said threaded protrusion rotatingly engages an aperture provided in an imaging device.

A12. The platform of claim A11, further comprising a cam having a threaded aperture defined therein which rotatingly engages said threaded protrusion.

A13. The platform of claim A1, wherein said first mount is a clip.

A14. The platform of claim A1, wherein said clip comprises a spring and first and second opposing jaws, and wherein said first and second jaws are movable from a first open position in which said jaws are spaced apart to a second closed position in which said jaws are in contact with each other.

A15. The platform of claim A9, wherein said spring is compressed when said clip is in said first position.

A16. The platform of claim A10, wherein said spring is relaxed when said clip is in the second position relative to when said clip is in said first position.

A17. The platform of claim A1, further comprising a resilient foam covering disposed over the surface of said arm.

A18. The platform of claim A12, wherein said covering comprises a foamed polymeric material.

A19. The platform of claim A12, wherein said covering comprises a foamed rubber.

A20. The platform of claim A1, wherein each of said first and second mounts comprise a cylindrical body.

A21. The platform of claim A1, wherein said second mount has a cylindrical body which encloses a portion of said flexible enclosure.

A22. The platform of claim A21, wherein said cylindrical body has a threaded protrusion extending from a surface thereof.

B1. A method for making a platform for an imaging device, comprising:
providing a rigid, deformable arm which comprises a particulate mass disposed within a flexible enclosure;
attaching a first end of the arm to a first connector which releasably attaches to a substrate; and
attaching a second end of the arm to a second connector which releasably attaches to an imaging device.

B2. The method of claim B1, wherein each of said first and second connectors comprises a cylindrical body, and wherein attaching a first end of the arm to the first connector includes inserting a portion of the flexible enclosure into the first connector.

B3. The method of claim B2, further comprising applying an adhesive to the portion of the flexible enclosure inserted into the first connector.

B4. The method of claim B1, wherein each of said first and second connectors comprise a cylindrical body, and wherein attaching a second end of the arm to the second connector includes inserting a portion of the flexible enclosure into the second connector.

B5. The method of claim B4, further comprising applying an adhesive to the portion of the flexible enclosure inserted into the second connector.

B6. The method of claim B1, wherein the flexible enclosure is a tube.

C1. A method for making a platform for an imaging device, comprising:
providing a first construct comprising a braided wire disposed within a hollow flexible tubing; and
attaching first and second connectors to first and second opposing ends of the first construct, thereby creating a second construct;
wherein the first mount releasably attaches to a substrate, and wherein the second connector releasably attaches to an imaging device.

C2. The method of claim C1, wherein the second connector comprises a threaded protrusion.

C3. The method of claim C1, wherein the first connector is a clamp.

C4. The method of claim C1, wherein the imaging device is a camera.

C5. The method of claim C1, wherein the imaging device is a digital recording device.

C6. The method of claim C1, further comprising forming the first construct by inserting the braided wire into the hollow tubing.

C7. The method of claim C6, wherein the braided wire is rotated about its longitudinal axis as it is inserted into the plastic tubing.

C8. The method of claim C1, wherein attaching first and second connectors to the first and second opposing ends of the first construct comprises attaching a first connector to a first end of the first construct, and attaching a second connector to a second end of the first construct.

C9. The method of claim C8, wherein the first connector is equipped with a concave portion on a first end thereof which is adapted to receive a first end of the tubing, and a threaded aperture on a second end thereof.

C10. The method of claim C9, further comprising:
rotatingly engaging a first threaded protrusion with the threaded aperture of the first connector.

C11. The method of claim C 10, wherein the second connector is equipped with a concave portion on a first end thereof which is adapted to receive a second end of the tubing, and a threaded aperture on a second end thereof.

C12. The method of claim C11, further comprising:
rotatingly engaging a second threaded protrusion with the threaded aperture of the second connector.

C13. The method of claim C12, wherein the first and second threaded protrusions rotatingly engage threaded apertures provided in the first and second connectors, respectively.

D1. A platform for an imaging device, comprising:
a braided wire disposed within a hollow flexible tubing; and
first and second connectors attached to first and second opposing ends of said first construct;
wherein the first connector releasably attaches to a substrate, and wherein the second connector releasably attaches to an imaging device.

D2. The platform of claim D1, wherein the second connector comprises a threaded protrusion.

D3. The platform of claim D1, wherein the first connector is a clamp.

D4. The platform of claim D1, wherein the imaging device is a camera.

D5. The platform of claim D1, wherein the imaging device is a digital recording device.

D6. The platform of claim D1, wherein the first connector is attached to the first end of the first construct by way of a first mating element, and wherein the second connector is attached to the second end of the first construct by way of a second mating element.

D7. The platform of claim D6, wherein the first connector is equipped with a concave portion on a first end thereof which is adapted to receive a first end of the tubing, and a threaded aperture on a second end thereof.

D8. The platform of claim D7, further comprising:
a first threaded protrusion which is rotatingly engaged with the threaded aperture of the first connector.

D9. The platform of claim D7, wherein the second connector is equipped with a concave portion on a first end thereof which is adapted to receive a second end of the tubing, and a threaded aperture on a second end thereof.

D10. The platform of claim D9, further comprising:
a second threaded protrusion which is rotatingly engaged with the threaded aperture of the second connector.

D11. The platform of claim D10, wherein the first and second threaded protrusions rotatingly engage threaded apertures provided in the first and second connectors, respectively.

E1. A platform for an imaging device, comprising:
a rigid, deformable arm containing a core material disposed within a flexible enclosure, wherein said core material is selected from the group consisting of (a) a particulate mass, and (b) a braided wire; and
first and second connectors attached to first and second opposing ends of said arm, wherein said second connector releasably attaches to an imaging device.

E2. The platform of claim E1, in combination with an imaging device.

E3. The platform of claim E1, wherein said first connector releasably attaches to a first mount.

E4. The platform of claim E3, wherein said first mount releasably attaches to a substrate.

E5. The platform of claim E3, wherein said first mount is a clip.

E6. The platform of claim E3, wherein said first mount is a spike.

E7. The platform of claim E1, wherein said second connector releasably attaches to an imaging device by way of a second mount.

E8. The platform of claim E1, wherein said enclosure is a tube.

E9. The platform of claim E8, wherein said tube is an elastomeric tube.

E10. The platform of claim E3, wherein said first connector is equipped with first and second mating elements, wherein said first mating element mates with said tube, and wherein said second mating element mates with said first mount.

E11. The platform of claim E10, wherein said first mating element of said first connector is a cylindrical receptacle.

E12. The platform of claim E10, wherein said second mating element of said first connector is selected from the group consisting of threaded protrusions and threaded apertures.

E13. The platform of claim E1, wherein said second connector is equipped with first and second mating elements, wherein said first mating element mates with said tube, and wherein said second mating element mates with the imaging device.

E14. The platform of claim E13, wherein said first mating element of said second connector is a cylindrical receptacle.

E15. The platform of claim E13, wherein said second mating element of said second connector is selected from the group consisting of threaded protrusions and threaded apertures.

E16. The platform of claim E13, wherein said second mating element of said second connector mates with the imaging device by way of a second mount.

E17. The platform of claim E10, wherein said first mount is a clip, and further comprising a fastener which fastens said first connector to said clip by rotatingly engaging said second mating element.

E18. The platform of claim E13, wherein said second mating element is a threaded protrusion which rotatingly engages an aperture provided in the imaging device.

E19. The platform of claim E18, further comprising a cam having a threaded aperture defined therein which rotatingly engages said threaded protrusion.

E20. The platform of claim E5, wherein said clip comprises a spring and first and second opposing jaws, and wherein said first and second jaws are movable from a first open position in which said jaws are spaced apart to a second closed position in which said jaws are in contact with each other.

E21. The platform of claim E20, wherein said spring is compressed when said clip is in said first position, and wherein said spring is relaxed when said clip is in the second position relative to when said clip is in said first position.

E22. The platform of claim E1, further comprising a resilient foam covering disposed over the surface of said arm.

E22. The platform of claim E1, wherein said core material is a particulate mass.

E23. The platform of claim E1, wherein said particulate mass is tightly packed within said enclosure.

E24. The platform of claim E1, wherein said particulate mass is a free flowing mass prior to being disposed in said enclosure.

E25. The platform of claim E1, wherein said particulate mass comprises a material selected from the group consisting of silica, sand, aluminum oxide and titanium oxide.

E26. The platform of claim E1, wherein said core material is a braided wire.
